(19) United States
(12) Patent Application Publication
(10) Pub. No.: US 2026/0361288 A1
(43) Pub. Date: Nov. 12, 2026

(54) ACOUSTIC WAVE DEVICE, FILTER, AND MULTIPLEXER

(71) Applicant: TAIYO YUDEN CO., LTD., Tokyo (JP)

(72) Inventors: Shodai HARAI, Tokyo (JP); Haruhiko YOSHITAKE, Tokyo (JP)

(73) Assignee: TAIYO YUDEN CO., LTD., Tokyo (JP)

(21) Appl. No.: 19/533,739

(22) Filed: Feb. 9, 2026

(30) Foreign Application Priority Data
Mar. 14, 2025 (JP) 2025-041475

(51) Int. Cl. H03H 9/145; H03H 9/00; H03H 9/02

(52) U.S. Cl. CPC H03H 9/1457; H03H 9/0038; H03H 9/0071; H03H 9/02834; H03H 9/14541

(57) ABSTRACT

An acoustic wave device includes a piezoelectric layer, a plurality of interdigital transducers (IDTs) provided on the piezoelectric layer, each of the IDTs including a pair of interdigitated electrodes, each of the pair of interdigitated electrodes including electrode fingers and a busbar, an intersection region in which the electrode fingers intersect each other including a pair of edge regions and a central region, and a load film provided in the pair of edge regions and not provided in the central region. The IDTs are connected in series by sharing a common busbar as the busbar between adjacent IDTs among the IDTs, and the load film provided in one of the edge regions and the load film provided in another of the edge regions are different in at least one of a thickness and a length in the longitudinal direction.

### CROSS-REFERENCE TO RELATED APPLICATION

This application claims priority based on Japanese Patent Application No. 2025-041475 filed on Mar. 14, 2025, the entire contents of the Japanese patent applications are incorporated herein by reference.

### FIELD

A certain aspect of the present disclosure relates to an acoustic wave device, a filter, and a multiplexer.

### BACKGROUND

In a high frequency communication system represented by a mobile phone, a high frequency filter is used to remove unnecessary signals other than a frequency band used for communication. An acoustic wave device is used for the high frequency filter. As an acoustic wave device, there has been known an acoustic wave device including an interdigital transducer (IDT) in which a pair of interdigitated electrodes that faces each other and each of pair of interdigitated electrodes that includes a plurality of electrode fingers and a busbar to which the plurality of electrode fingers are connected. It is known that the acoustic velocity of the acoustic wave in the edge regions located at the longitudinal edges of the electrode fingers in the intersection region where the electrode fingers of pair of interdigitated electrodes intersect is slower than the acoustic velocity of the acoustic wave in the central region located inside the edge regions, thereby realizing a piston mode and suppressing transverse mode spurious emissions (for example, Japanese Patent Application Publication No. 2016-136712). It is also known that the IDT is divided in series in order to improve the power durability (for example, Japanese Patent Application Publication No. 2016-82570).

### SUMMARY OF THE INVENTION

According to a first aspect of the present disclosure, there is provided an acoustic wave device including: a piezoelectric layer; a plurality of interdigital transducers (IDTs) provided on the piezoelectric layer so as to be connected in series to each other, each of the IDTs including a pair of interdigitated electrodes, each of the pair of interdigitated electrodes including a plurality of electrode fingers and a busbar to which the plurality of electrode fingers are connected, an intersection region in which the plurality of electrode fingers of the pair of interdigitated electrodes intersect each other including a pair of edge regions located at edges of the plurality of electrode fingers in a longitudinal direction and a central region located between the pair of edge regions; and a load film provided in the pair of edge regions and not provided in the central region in each of the plurality of IDTs; wherein the plurality of IDTs are connected in series by sharing a common busbar as the busbar between adjacent IDTs among the plurality of IDTs, and wherein in each of a first IDT and a second IDT located at both ends in the longitudinal direction among the plurality of IDTs, the load film provided in one of the pair of edge regions and the load film provided in another of the pair of edge regions are different in at least one of a thickness and a length in the longitudinal direction.

According to a second aspect of the present disclosure, there is provided an acoustic wave device including: a piezoelectric layer; a plurality of interdigital transducers (IDTs) provided on the piezoelectric layer so as to be connected in series to each other, each of the IDTs including a pair of interdigitated electrodes, each of the pair of interdigitated electrodes including a plurality of electrode fingers and a busbar to which the plurality of electrode fingers are connected, an intersection region in which the plurality of electrode fingers of the pair of interdigitated electrodes intersect each other including a pair of edge regions located at edges of the plurality of electrode fingers in a longitudinal direction and a central region located between the pair of edge regions; and a load film provided in the pair of edge regions and not provided in the central region in each of the plurality of IDTs; wherein the plurality of IDTs are connected in series by sharing a common busbar as the busbar between adjacent IDTs among the plurality of IDTs, and wherein in each of a first IDT and a second IDT located at both ends in the longitudinal direction among the plurality of IDTs, a distance between the plurality of electrode fingers of one of the pair of interdigitated electrodes and the busbar of another of the pair of interdigitated electrodes is different from a distance between the busbar of the one of the pair of interdigitated electrodes and the plurality of electrode fingers of the another of the pair of interdigitated electrodes.

According to a third aspect of the present disclosure, there is provided an acoustic wave device including: a piezoelectric layer; and a plurality of interdigital transducers (IDTs) provided on the piezoelectric layer so as to be connected in series to each other, each of the IDTs including a pair of interdigitated electrodes, each of the pair of interdigitated electrodes including a plurality of electrode fingers and a busbar to which the plurality of electrode fingers are connected, an intersection region in which the plurality of electrode fingers of the pair of interdigitated electrodes intersect each other including a pair of edge regions located at edges of the plurality of electrode fingers in a longitudinal direction and a central region located between the pair of edge regions, lengths of the plurality of electrode fingers in a transverse direction of the plurality of electrode fingers in the pair of edge regions being larger than lengths of the plurality of electrode fingers in the transverse direction in the central region; wherein the plurality of IDTs are connected in series by sharing a common busbar as the busbar between adjacent IDTs among the plurality of IDTs, and wherein in each of a first IDT and a second IDT located at both ends in the longitudinal direction among the plurality of IDTs, at least one of lengths in the longitudinal direction and lengths in the transverse direction of the plurality of electrode fingers is different between one and another of the pair of edge regions.

According to a fourth aspect of the present disclosure, there is provided an acoustic wave device including: a piezoelectric layer; and a plurality of interdigital transducers (IDTs) provided on the piezoelectric layer so as to be connected in series to each other, each of the IDTs including a pair of interdigitated electrodes, each of the pair of interdigitated electrodes including a plurality of electrode fingers and a busbar to which the plurality of electrode fingers are connected, an intersection region in which the plurality of electrode fingers of the pair of interdigitated electrodes intersect each other including a pair of edge regions located at edges of the plurality of electrode fingers in a longitudinal direction and a central region located between the pair of edge regions, lengths of the plurality of electrode fingers in a transverse direction of the plurality of electrode fingers in the pair of edge regions being larger than lengths of the plurality of electrode fingers in the transverse direction in the central region; wherein the plurality of IDTs are connected in series by sharing a common busbar as the busbar between adjacent IDTs among the plurality of IDTs, and wherein in each of a first IDT and a second IDT located at both ends in the longitudinal direction among the plurality of IDTs, a distance between the plurality of electrode fingers of one of the pair of interdigitated electrodes and the busbar of another of the pair of interdigitated electrodes is different from a distance between the busbar of the one of the pair of interdigitated electrodes and the plurality of electrode fingers of the another of the pair of interdigitated electrodes.

According to a fifth aspect of the present disclosure, there is provided an acoustic wave device including: a piezoelectric layer; and a plurality of interdigital transducers (IDTs) provided on the piezoelectric layer so as to be connected in series to each other, each of the IDTs including a pair of interdigitated electrodes, each of the pair of interdigitated electrodes including a plurality of electrode fingers and a busbar to which the plurality of electrode fingers are connected, an intersection region in which the plurality of electrode fingers of the pair of interdigitated electrodes intersect each other including a pair of edge regions located at edges of the plurality of electrode fingers in a longitudinal direction and a central region located between the pair of edge regions, an acoustic velocity of an acoustic wave in the pair of edge regions being lower than that of an acoustic wave in the central region; wherein the plurality of IDTs are connected in series by sharing a common busbar as the busbar between adjacent IDTs among the plurality of IDTs, and wherein in each of a first IDT and a second IDT located at both ends in the longitudinal direction among the plurality of IDTs, an acoustic velocity profile of an acoustic wave from a boundary between the plurality of electrode fingers of one of the pair of interdigitated electrodes and the busbar to a boundary between the plurality of electrode fingers of another of the pair of interdigitated electrodes and the busbar is asymmetric with respect to a center of the central region.

### BRIEF DESCRIPTION OF THE DRAWINGS

FIG. 1A is a plan view of an acoustic wave device according to a first comparative example.

FIG. 1B is a cross-sectional view taken along a line A-A in FIG. 1A.

FIG. 2 is a diagram illustrating the acoustic velocity of an acoustic wave in an acoustic wave device according to the first comparative example.

FIG. 3A is a plan view of an acoustic wave device according to a second comparative example.

FIG. 3B is a cross-sectional view taken along a line A-A in FIG. 3A.

FIG. 4 is a diagram illustrating the acoustic velocity of an acoustic wave in an acoustic wave device according to a second comparative example.

FIG. 5 is a diagram illustrating simulation results of real part Real (Y) and absolute value |Y| of admittance with respect to frequency in simulation 1.

FIG. 6A is a plan view of an acoustic wave device according to a first embodiment.

FIG. 6B is a cross-sectional view taken along a line A-A in FIG. 6A.

FIG. 7 is a diagram illustrating the acoustic velocity of the acoustic wave of an acoustic wave device according to a first embodiment.

FIGS. 8A to 8C are diagrams illustrating simulation results of real part Real (Y) and absolute value |Y| of admittance with respect to frequency in simulation 2.

FIG. 9A is a plan view of an acoustic wave device according to a modification of the first embodiment.

FIG. 9B is a cross-sectional view of the acoustic wave device according to the modification of the first embodiment.

FIG. 9C is a diagram illustrating the acoustic velocity of the acoustic wave.

FIG. 10A is a plan view of an acoustic wave device according to a second embodiment.

FIG. 10B is a cross-sectional view of the acoustic wave device according to the second embodiment.

FIG. 10C is a diagram illustrating the acoustic velocity of the acoustic wave.

FIG. 11A is a plan view of an acoustic wave device according to a third embodiment.

FIG. 11B is a cross-sectional view of the acoustic wave device according to the third embodiment.

FIG. 11C is a diagram illustrating the acoustic velocity of the acoustic wave.

FIG. 12A is a plan view of an acoustic wave device according to a modification of a third embodiment.

FIG. 12B is a cross-sectional view of the acoustic wave device according to the modification of the third embodiment.

FIG. 12C is a diagram illustrating the acoustic velocity of the acoustic wave.

FIG. 13A is a plan view of an acoustic wave device according to a fourth embodiment.

FIG. 13B is a cross-sectional view of the acoustic wave device according to the fourth embodiment.

FIG. 13C is a diagram illustrating the acoustic velocity of the acoustic wave.

FIG. 14A is a plan view of an acoustic wave device according to a modification of a fourth embodiment.

FIG. 14B is a cross-sectional view of the acoustic wave device according to the modification of the fourth embodiment.

FIG. 14C is a diagram illustrating the acoustic velocity of the acoustic wave.

FIG. 15A is a plan view of an acoustic wave device according to a fifth embodiment.

FIG. 15B is a cross-sectional view of the acoustic wave device according to the fifth embodiment.

FIG. 15C is a diagram illustrating the acoustic velocity of the acoustic wave.

FIG. 16A is a plan view of an acoustic wave device according to a sixth embodiment.

FIG. 16B is a cross-sectional view of the acoustic wave device according to the sixth embodiment.

FIG. 16C is a diagram illustrating the acoustic velocity of the acoustic wave.

FIG. 17A is a circuit diagram of a filter according to a seventh embodiment.

FIG. 17B is a circuit diagram of a duplexer according to a modification of the seventh embodiment.

### DESCRIPTION OF EMBODIMENTS

When the IDT is divided in series, the piston mode is not established, and the transverse mode spurious emissions may occur.

The present disclosure has been made in view of the above problems, and an object of the present disclosure is to suppress transverse mode spurious emissions.

First, a comparative example will be described in order to clarify the problems to be solved by the embodiments of the present disclosure.

### First Comparative Example

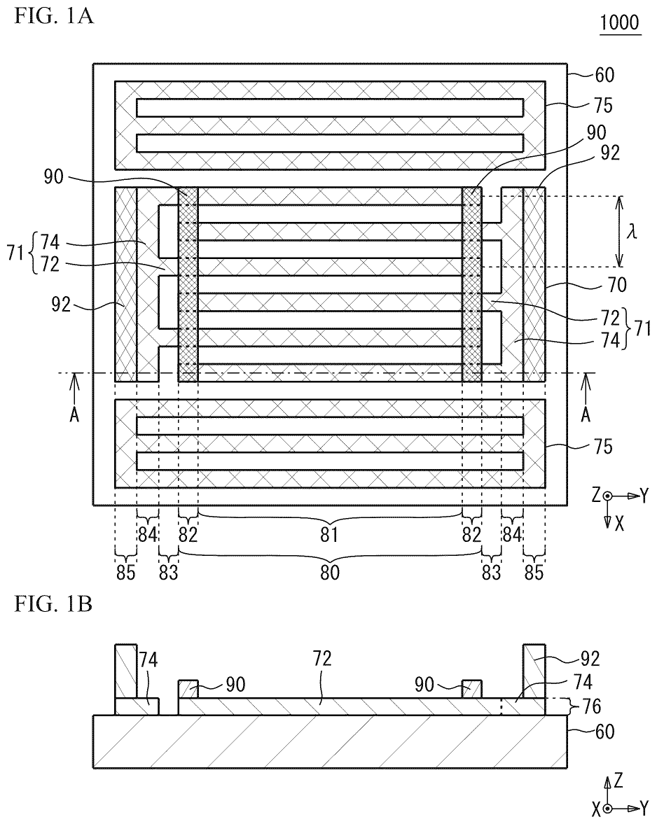

FIG. 1A is a plan view of an acoustic wave device 1000 according to a first comparative example, and FIG. 1B is a cross-sectional view taken along a line A-A in FIG. 1A. The transverse direction of electrode fingers 72 is defined as an X direction, the longitudinal direction is defined as a Y direction, and a thickness direction of the piezoelectric layer 60 is defined as a Z direction. As illustrated in FIG. 1A and FIG. 1B, an interdigital transducer (IDT) 70 and reflectors 75 are provided on the piezoelectric layer 60. The IDT 70 includes a pair of interdigitated electrodes 71. The interdigitated electrode 71 includes the plurality of electrode fingers 72 and a busbar 74 to which the plurality of electrode fingers 72 are connected. The IDT 70 and the reflector 75 are formed by a metal film 76 on the piezoelectric layer 60. A metal film 92 is provided on a part of the busbar 74.

A region where the electrode fingers 72 of the pair of interdigitated electrodes 71 intersect is an intersection region 80. The acoustic wave of the main mode excited by the electrode fingers 72 in the intersection region 80 mainly propagates in the X direction. The pitch of the electrode fingers 72 of the interdigitated electrode 71 is substantially equal to the wavelength λ of the acoustic wave. The reflectors 75 are provided with the IDT 70 interposed therebetween in the X direction, and reflect a surface acoustic wave (SAW) excited by the finger electrodes 72. As a result, the surface acoustic wave is confined within the intersection region 80 of the IDT 70.

The intersection region 80 includes edge regions 82 located at edges in the Y direction and a central region 81 located inside the edge regions 82 in the Y direction. Regions located between the tips of the electrode fingers 72 of one interdigitated electrode 71 and the busbar 74 of the other interdigitated electrode 71 are gap regions 83. In the regions where the busbars 74 are located, regions where the metal film 92 is not provided are first busbar regions 84, and regions where the metal film 92 is provided is second busbar regions 85.

A load film 90 is provided on the piezoelectric layer 60 in the edge regions 82. The load film 90 is provided to extend in a band shape in the X direction. The load film 90 is not provided in the central region 81, the gap regions 83, the first busbar regions 84, and the second busbar regions 85.

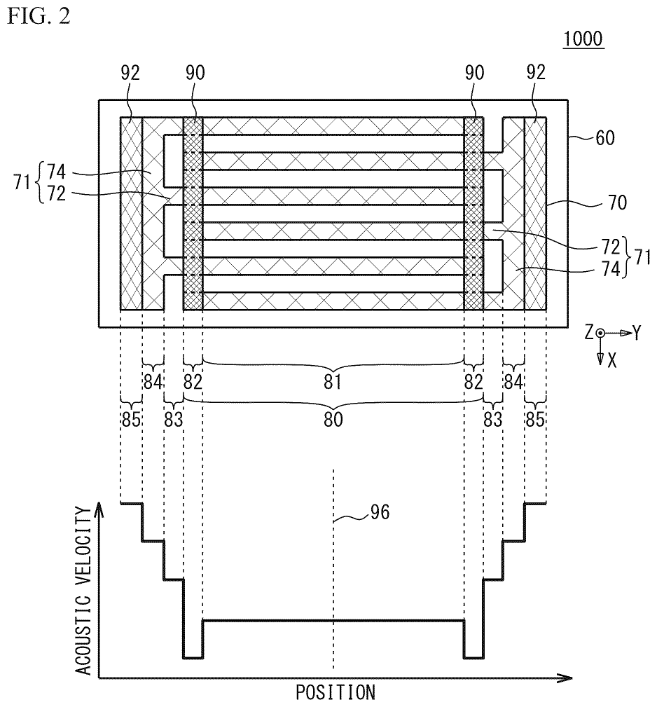

FIG. 2 is a diagram illustrating the acoustic velocity of an acoustic wave in the acoustic wave device 1000 according to the first comparative example. As illustrated in FIG. 2, since the load film 90 is provided in the edge regions 82, the acoustic velocity of the acoustic wave propagating through the edge regions 82 is lower than the acoustic velocity of the acoustic wave propagating through the central region 81. Since the number of electrode fingers 72 in the gap regions 83 is smaller than that in the central region 81, the acoustic velocity of the acoustic wave propagating through the gap regions 83 is higher than the acoustic velocity of the acoustic wave propagating through the central region 81. The acoustic velocity of the acoustic wave propagating through the first busbar regions 84 is higher than the acoustic velocity of the acoustic wave propagating through the gap regions 83, for example. The acoustic velocity of the acoustic wave propagating through the second busbar regions 85 is higher than the acoustic velocity of the acoustic wave propagating through the first busbar regions 84, for example. The edge regions 82 are low acoustic velocity regions in which the acoustic velocity of the acoustic wave is lower than that in the central region 81, and the gap regions 83 are high acoustic velocity regions in which the acoustic velocity of the acoustic wave is higher than that in the central region 81, and thus, the piston mode can be realized.

### Second Comparative Example

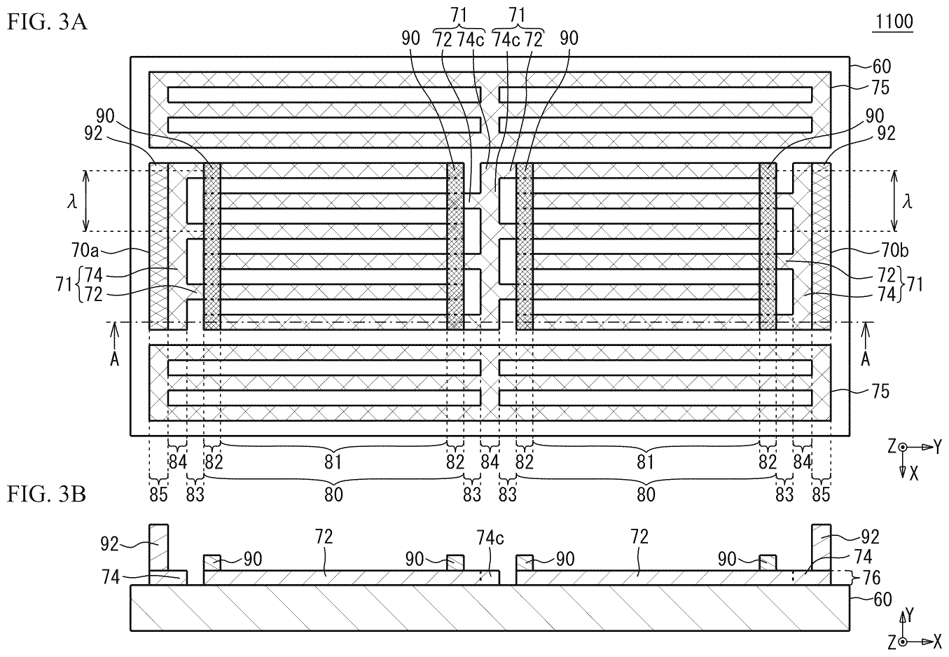

A second comparative example is an example in which the IDT 70 in a first comparative example is divided in series. FIG. 3A is a plan view of an acoustic wave device 1100 according to a second comparative example, and FIG. 3B is a cross-sectional view taken along a line A-A in FIG. 3A. As illustrated in FIG. 3A and FIG. 3B, a first IDT 70a and a second IDT 70b connected in series to the first IDT 70a are provided on the piezoelectric layer 60. Each of the first IDT 70a and the second IDT 70b includes the pair of interdigitated electrodes 71. One of the pair of interdigitated electrodes 71 in the first IDT 70a and one of the pair of interdigitated electrodes 71 in the second IDT 70b share one common busbar 74c. The metal film 92 is not provided on the common busbar 74c. The metal film 92 is provided on the busbar 74 of the other of the interdigitated electrodes 71 in the first IDT 70a and on the busbar 74 of the other of the interdigitated electrodes 71 in the second IDT 70b. The wavelength λ of the acoustic wave of the first IDT 70a and the wavelength λ of the acoustic wave of the second IDT 70b are the same as each other. In each of the first IDT 70a and the second IDT 70b, the load film 90 is provided in the edge regions 82. The other configurations are the same as those of the first comparative example, and thus the description thereof will be omitted.

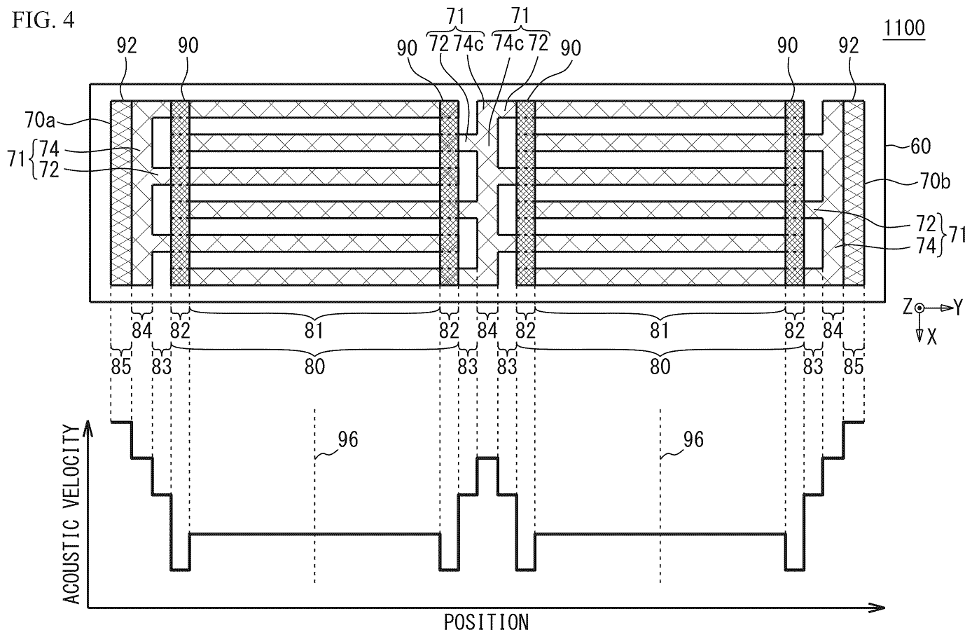

FIG. 4 is a diagram illustrating the acoustic velocity of an acoustic wave in the acoustic wave device 1100 according to a second comparative example. As illustrated in FIG. 4, since the load film 90 is provided in the edge regions 82 in each of the first IDT 70a and the second IDT 70b, the acoustic velocity of the acoustic wave propagating through the edge regions 82 is lower than the acoustic velocity of the acoustic wave propagating through the central region 81. Since the number of electrode fingers 72 in the gap regions 83 is smaller than that in the central region 81, the acoustic velocity of the acoustic wave propagating through the gap regions 83 is higher than the acoustic velocity of the acoustic wave propagating through the central region 81. In each of the first IDT 70a and the second IDT 70b, the edge regions 82 are low acoustic velocity regions in which the acoustic velocity of the acoustic wave is lower than that in the central region 81, and the gap regions 83 are high acoustic velocity regions in which the acoustic velocity of the acoustic wave is higher than that in the central region 81, and thus, the piston mode can be realized.

### Simulation 1

A simulation for measuring a real part Real (Y) and an absolute value |Y| of admittance was performed on the first comparative example and the second comparative example. The simulation conditions are as follows.
Wavelength λ of acoustic wave: 2.2 μm
Piezoelectric layer 60:42° rotated Y-cut X-propagation lithium tantalate layer
Metal film 76: aluminum film having thickness of 220 nm
Load film 90: niobium oxide film having thickness of 16 nm
Metal film 92: gold film having thickness of 1 μm
Anisotropy coefficient of piezoelectric layer 60:0.3
Duty ratio of electrode finger 72:50 %
Length of central region 81 in Y direction: 15 λ
Length of edge region 82 in Y direction: 0.6 λ
Length of gap region 83 in Y direction: 100 nm
Length of first busbar region 84 (common busbar 74c) in Y direction: 1 μm
Length of second busbar region 85 in Y direction: 20 μm
Ratio (V_{B}−V_{A})/V_{A} of difference between acoustic velocity V_{B} in edge region 82 and acoustic velocity V_{A} in central region 81 to acoustic velocity V_{A} in central region 81:−1.5 %
Ratio (V_{C}−V_{A})/V_{A} of difference between acoustic velocity V_{C} in gap region 83 and acoustic velocity V_{A} in central region to acoustic velocity V_{A} in central region 81:+3.0 %
Ratio (V_{D}−V_{A})/V_{A} of difference between acoustic velocity V_{D} in first busbar region 84 and acoustic velocity V_{A} in central region to acoustic velocity V_{A} in central region 81:+4.0 %
Ratio (V_{E}−V_{A})/V_{A} of difference between acoustic velocity V_{E} in second busbar region 85 and acoustic velocity V_{A} in central region to acoustic velocity V_{A} in central region 81:+10 %

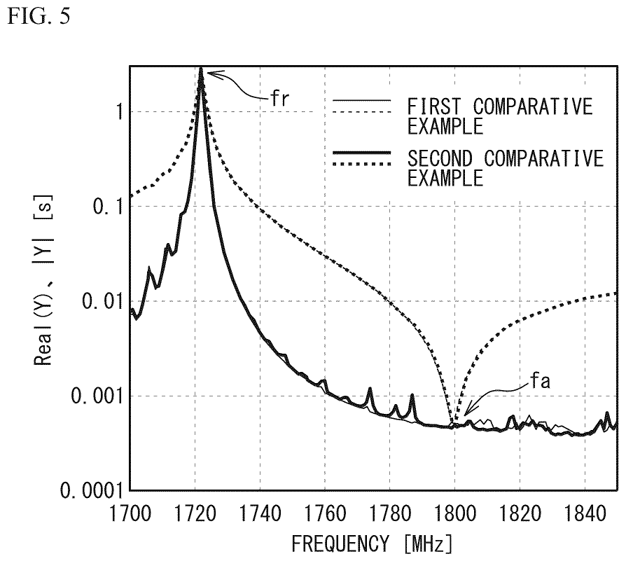

FIG. 5 is a diagram illustrating simulation results of real part Real (Y) of admittance and absolute value |Y| of admittance with respect to frequency in simulation 1. In FIG. 5, the result of the first comparative example is indicated by a thin line, the result of the second comparative example is indicated by a thick line, the result of the real part Real (Y) of the admittance is indicated by a solid line, and the result of the absolute value |Y| of the admittance is indicated by a dotted line. In the absolute value |Y| of the admittance, peaks of the resonance frequency fr and the antiresonance frequency fa are observed. In the real part Real (Y) of the admittance, a spurious response is observed to be larger than that in the absolute value |Y|.

As illustrated in FIG. 5, the transverse mode spurious emissions between the resonant frequency fr and the anti-resonant frequency fa increase in the second comparative example compared to the first comparative example. This is considered to be due to the following reasons. As illustrated in FIG. 2, in the first comparative example, the acoustic velocity profile of the acoustic wave is symmetrical with respect to a center line 96 of the central region 81. In contrast, in the second comparative example, as illustrated in FIG. 4, since the metal film 92 is not provided on the common busbar 74c, the acoustic velocity profile of the acoustic wave is asymmetric with respect to the center line 96 of the central region 81 in each of the first IDT 70a and the second IDT 70b. Therefore, it is considered that, when the conditions under which the piston mode is established in the first comparative example are applied to the second comparative example as they are, the piston mode is not established in the second comparative example, and the transverse mode spurious emissions increase. As described above, the inventors have found for the first time that even when the conditions of the piston mode established before the division of the IDT are applied as they are after the division of the IDT, the piston mode is not established and the transverse mode spurious emissions cannot be suppressed.

Therefore, an example in which the transverse mode spurious emissions can be suppressed even when the IDT is divided in series will be described below.

### FIRST EMBODIMENT

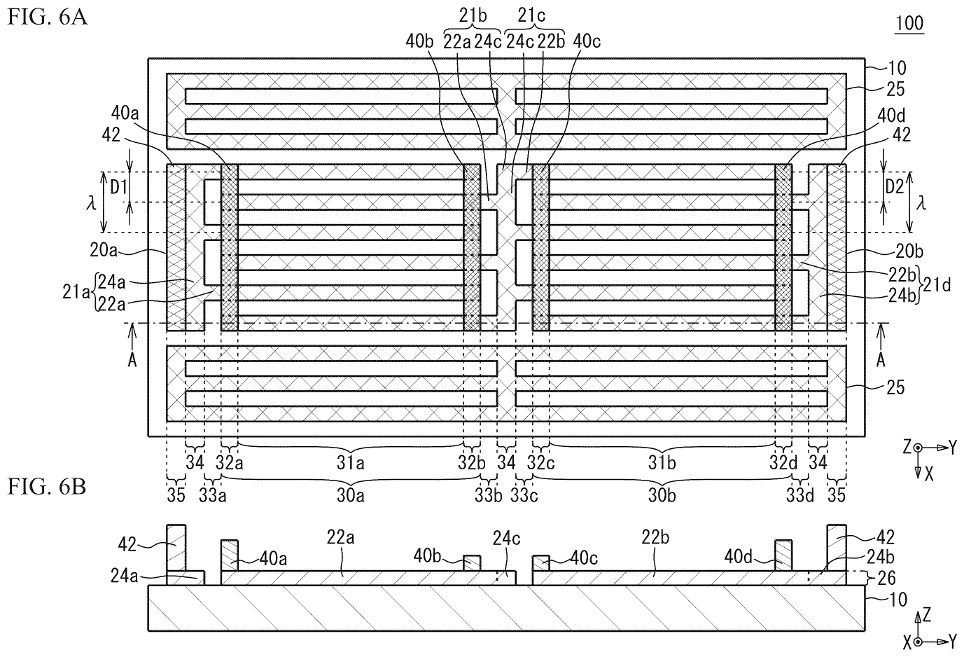

A first embodiment is an example of a case where one IDT is divided into two portions, that is, a first IDT 20a and a second IDT 20b in series. FIG. 6A is a plan view of an acoustic wave device 100 according to a first embodiment, and FIG. 6B is a cross-sectional view taken along a line A-A in FIG. 6A. The transverse direction of electrode fingers 22a and 22b is defined as the X direction, the longitudinal direction is defined as the Y direction, and the thickness direction of a piezoelectric layer 10 is defined as the Z direction. The X direction, the Y direction, and the Z direction do not necessarily correspond to the X-axis direction of the crystal orientation of the piezoelectric layer 10. When the piezoelectric layer 10 is a rotated Y-cut X-propagation piezoelectric layer, the X direction is the X-axis direction of the crystal orientation.

As illustrated in FIGS. 6A and 6B, the first IDT 20a, the second IDT 20b connected in series to the first IDT 20a, and reflectors 25 interposing the first IDT 20a and the second IDT 20b from the X direction are provided on the piezoelectric layer 10. The first IDT 20a, the second IDT 20b and the reflectors 25 are formed by a metal film 26 on the piezoelectric layer 10. The piezoelectric layer 10 may be a thick substrate, or may be provided on a support substrate such as a sapphire substrate, an alumina substrate, a spinel substrate, a quartz substrate, a crystal substrate, a silicon carbide substrate, or a silicon substrate. An insulating layer such as silicon oxide, aluminum oxide, and/or aluminum nitride may be provided between a support substrate and the piezoelectric layer 10.

The first IDT 20a includes a pair of opposing interdigitated electrodes 21a and 21b. The interdigitated electrode 21a includes the plurality of electrode fingers 22a and a busbar 24a to which the electrode fingers 22a are connected. The interdigitated electrode 21b includes a plurality of electrode fingers 22a and a common busbar 24c to which the electrode fingers 22a are connected.

A region where the electrode fingers 22a of the interdigitated electrodes 21a and 21b intersect is an intersection region 30a. The interdigitated electrodes 21a and 21b face each other such that the electrode fingers 22a are alternately arranged in the X direction in at least a part of the intersection region 30a. In the intersection region 30a, the acoustic wave (surface acoustic wave) of the main mode excited by the electrode finger 22a propagates mainly in the X direction. The pitch of the electrode fingers 22a of one of the interdigitated electrodes 21a and 21b is substantially equal to the wavelength λ of the acoustic wave. The wavelength λ is substantially twice an average pitch D1 of the plurality of electrode fingers 22a. The reflectors 25 reflect the surface acoustic wave excited by the electrode fingers 22a of the first IDT 20a. As a result, the surface acoustic wave is confined within the intersection region 30a of the first IDT 20a. A metal film 42 is provided on a part of the busbar 24a.

The intersection region 30a includes a pair of edge regions 32a and 32b located at the edges in the Y direction, and a central region 31a located between the edge regions 32a and 32b. A region located between the busbar 24a of the interdigitated electrode 21a and the tips of the electrode fingers 22a of the interdigitated electrode 21b is a gap region 33a. A region located between the common busbar 24c of the interdigitated electrode 21b and the tips of the electrode fingers 22a of the interdigitated electrode 21a is a gap region 33b. In the regions where the busbar 24a and the common busbar 24c are located, a region where the metal film 42 is not provided is a first busbar region 34, and a region where the metal film 42 is provided is a second busbar region 35.

The second IDT 20b includes a pair of opposing interdigitated electrodes 21c and 21d. The interdigitated electrode 21c includes the plurality of electrode fingers 22b and the common busbar 24c to which the electrode fingers 22b are connected. The interdigitated electrode 21d includes the plurality of electrode fingers 22b and a busbar 24b to which the electrode fingers 22b are connected. In this way, the interdigitated electrodes 21b of the first IDT 20a and the interdigitated electrodes 21c of the second IDT 20b share one common busbar 24c. The length of the common busbar 24c in the Y direction is, for example, 0.3 λ or more and 2.0 λ or less. The metal film 42 is not provided on the common busbar 24c.

A region where the electrode fingers 22b of the interdigitated electrodes 21c and 21d intersect is an intersection region 30b. The interdigitated electrodes 21c and 21d face each other such that the electrode fingers 22b are alternately arranged in the X direction in at least a part of the intersection region 30b. In the intersection region 30b, the acoustic wave (surface acoustic wave) of the main mode excited by the electrode fingers 22b propagates mainly in the X direction. The pitch of the electrode fingers 22b of one of the interdigitated electrodes 21c and 21d is substantially equal to the wavelength λ of the acoustic wave. The wavelength λ is substantially twice an average pitch D2 of the plurality of electrode fingers 22b. The average pitch D2 and the average pitch D1 are the same as each other. The same average pitch means that the ratio of the difference in average pitch to one average pitch is 3% or less. The average pitches D1 and D2 can be calculated by dividing the lengths of the first IDT 20a and the second IDT 20b in the X direction by the numbers of the electrode finger 22a and 22b, respectively. The reflectors 25 reflect the surface acoustic wave excited by the electrode fingers 22b of the second IDT 20b. As a result, the surface acoustic wave is confined within the intersection region 30b of the second IDT 20b. The metal film 42 is provided on a part of the busbar 24b.

The intersection region 30b includes a pair of edge regions 32c and 32d located at the edges in the Y direction, and a central region 31b located between the edge regions 32c and 32d. A region located between the common busbar 24c of the interdigitated electrode 21c and the tips of the electrode fingers 22b of the interdigitated electrode 21d is a gap region 33c. A region located between the busbar 24b of the interdigitated electrode 21d and the tips of the electrode fingers 22b of the interdigitated electrode 21c is a gap region 33d. In the regions where the busbar 24b and the common busbar 24c are located, the region where the metal film 42 is not provided is the first busbar region 34, and the region where the metal film 42 is provided is the second busbar region 35.

In the first IDT 20a, a load film 40a is provided on the piezoelectric layer 10 in the edge region 32a, and a load film 40b is provided on the piezoelectric layer 10 in the edge region 32b. The load films 40a and 40b are provided to extend in a band shape in the X direction and cover the electrode fingers 22a located in the edge regions 32a and 32b. The load film 40a and the load film 40b have the same length in the Y direction, but have different thicknesses. The difference in thickness of the load films means that, for example, the ratio of the difference in thickness of the load films to the thickness of one of the load films is 10% or more, but may be 15% or more, or 20% or more (the same applies hereinafter). The thickness of the load film 40a may be larger or smaller than the thickness of the load film 40b. The lengths of the load films being the same allows a case where the ratio of the difference in the length of the load film to the length of one load film is 3% or less (the same applies hereinafter). The load film is not provided in the central region 31a, the gap regions 33a and 33b, the first busbar regions 34, and the second busbar regions 35.

In the second IDT 20b, a load film 40c is provided on the piezoelectric layer 10 in the edge region 32c, and a load film 40d is provided on the piezoelectric layer 10 in the edge region 32d. The load films 40c and 40d are provided to extend in a band shape in the X direction and cover the electrode fingers 22b located in the edge regions 32c and 32d. The load film 40c and the load film 40d have the same length in the Y direction, but have different thicknesses. The thickness of the load film 40d may be larger or smaller than the thickness of the load film 40c. The load film 40c has the same length in the Y direction and the same thickness as the load film 40b, and the load film 40d has the same length in the Y direction and the same thickness as the load film 40a. The same thickness of the load films allows a case where a ratio of a difference in thickness of the load films to a thickness of one of the load films is 3% or less (the same applies hereinafter). The load film is not provided in the central region 31b, the gap regions 33c and 33d, the first busbar region 34, and the second busbar region 35.

The piezoelectric layer 10 is formed of, for example, single crystal lithium tantalate or single crystal lithium niobate, and is formed of, for example, rotated Y-cut X-propagation lithium tantalate or rotated Y-cut X-propagation lithium niobate. The piezoelectric layer 10 may be, for example, a 30° to 50° Y-cut X-propagation lithium tantalate layer. The metal film 26 is a film containing, for example, aluminum, copper, molybdenum, iridium, platinum, rhenium, rhodium, ruthenium, tantalum, or tungsten as a main component. The load films 40a to 40d are insulating films including silicon oxide, tantalum oxide, or niobium oxide as a main component, but may be a single-layer or multilayer film including another material as a main component as long as the acoustic velocity of the acoustic wave propagating through the edge regions 32a to 32d can be adjusted. The metal film 42 is, for example, a gold film or a copper film.

Here, in order to make a certain film contain a certain element as its main component, the certain film may contain an intentional or unintentional impurity other than the main component. When a certain element is a main component in a certain film, the concentration of the certain element is, for example, 50 atomic% or more, and for example, 80 atomic% or more. In the case where the main component is two or more elements, such as silicon oxide, the total concentration of the two or more elements is 50 atomic% or more, 80 atomic% or more, or 90 atomic% or more. Each of the two or more elements is 10 atomic% or more or 20 atomic%.

### Manufacturing Method

A method of manufacturing the acoustic wave device 100 according to the first embodiment will be described. After the metal film 26 is formed on the piezoelectric layer 10, the metal film 26 is patterned into a desired shape. Thus, the first IDT 20a, the second IDT 20b, and the reflectors 25 are formed on the piezoelectric layer 10. The metal film 26 is formed by, for example, a sputtering method, a vacuum deposition method, or a chemical vapor deposition (CVD) method. The patterning of the metal film 26 is performed by, for example, a photolithography method and an etching method.

Next, the load films 40b and 40c are formed using a mask layer having openings in the edge regions 32b and 32c as a mask, and then the mask layer is removed. Thereby, the load film 40b is formed in the edge region 32b, and the load film 40c is formed in the edge region 32c. The load films 40a and 40d are formed by using a mask layer having openings in the edge regions 32a and 32d as a mask, and then the mask layer is removed. Thereby, the load film 40a is formed in the edge region 32a, and the load film 40d is formed in the edge region 32d. The load film is formed by, for example, the sputtering method, the vacuum deposition method, or the CVD method. As described above, the acoustic wave device 100 according to the first embodiment is formed. In the case where the piezoelectric layer 10 is provided on a support substrate, the piezoelectric layer 10 is bonded onto the support substrate by, for example, a surface activation method, and then the piezoelectric layer 10 is polished to a desired thickness by, for example, a chemical mechanical polishing (CMP) method.

### Acoustic Velocity of Acoustic Wave

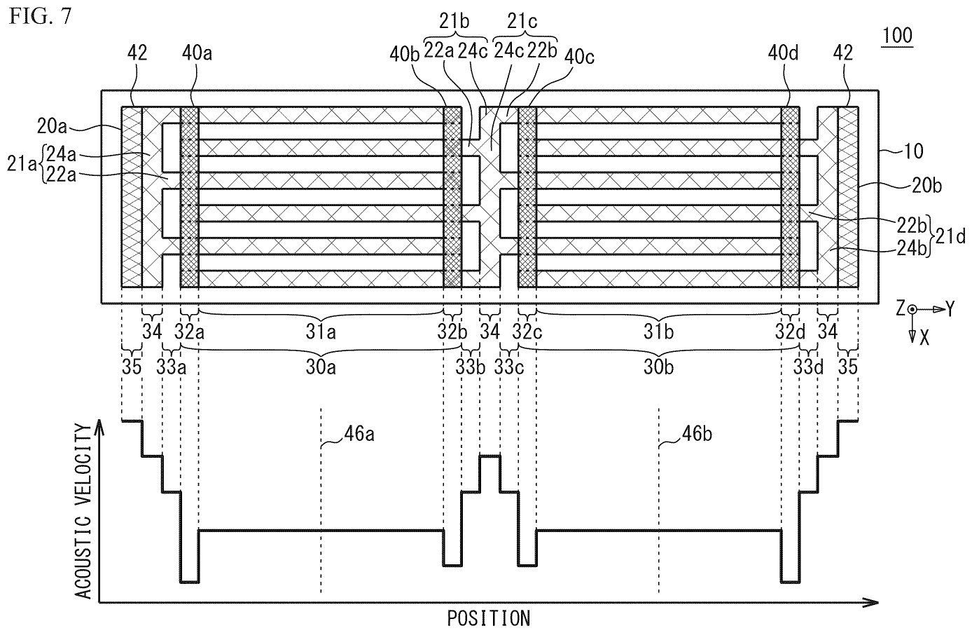

FIG. 7 is a diagram illustrating the acoustic velocity of the acoustic wave of the acoustic wave device 100 according to the first embodiment. As illustrated in FIG. 7, in the first IDT 20a, the load film 40a is provided in the edge region 32a, and the load film 40b is provided in the edge region 32b, and thus the acoustic velocity of the acoustic wave propagating through the edge regions 32a and 32b is lower than the acoustic velocity of the acoustic wave propagating through the central region 31a. As illustrated in FIG. 6B, since the load film 40a and the load film 40b have different thicknesses, the acoustic velocity of the propagating acoustic wave is different between the edge region 32a and the edge region 32b. The difference in acoustic velocity between the edge regions means that the difference between the ratio of the acoustic velocity difference between one edge region and the central region to the acoustic velocity of the central region and the ratio of the acoustic velocity difference between the other edge region and the central region to the acoustic velocity of the central region is 0.5% or more, may be 0.8% or more, and may be 1.0% or more (the same applies hereinafter). For example, when the load film 40a is thicker than the load film 40b, the acoustic velocity of the acoustic wave propagating through the edge region 32a is lower than the acoustic velocity of the acoustic wave propagating through the edge region 32b.

Since the number of the electrode fingers 22a in the gap regions 33a and 33b is smaller than that in the central region 31a, the acoustic velocity of the acoustic wave propagating through the gap regions 33a and 33b is higher than the acoustic velocity of the acoustic wave propagating through the central region 31a. The acoustic velocity of the acoustic wave propagating through the first busbar region 34 is higher than the acoustic velocity of the acoustic wave propagating through the gap regions 33a and 33b, for example. The acoustic velocity of the acoustic wave propagating through the second busbar region 35 is higher than the acoustic velocity of the acoustic wave propagating through the first busbar region 34, for example. The edge regions 32a and 32b are low acoustic velocity regions in which the acoustic velocity of the acoustic wave is lower than that in the central region 31a, and the gap regions 33a and 33b are high acoustic velocity regions in which the acoustic velocity of the acoustic wave is higher than that in the central region 31a, and thus, the piston mode can be realized.

In the second IDT 20b, since the load film 40c is provided in the edge region 32c and the load film 40d is provided in the edge region 32d, the acoustic velocity of the acoustic wave propagating through the edge regions 32c and 32d is lower than the acoustic velocity of the acoustic wave propagating through the central region 31b. As illustrated in FIG. 6B, since the load film 40c and the load film 40d have different thicknesses, the acoustic velocity of the propagating acoustic wave is different between the edge region 32c and the edge region 32d. For example, when the load film 40d is thicker than the load film 40c, the acoustic velocity of the acoustic wave propagating through the edge region 32d is lower than the acoustic velocity of the acoustic wave propagating through the edge region 32c.

Since the load film 40b and the load film 40c have the same thickness, the acoustic velocity of the acoustic wave propagating through the edge region 32b and the acoustic velocity of the acoustic wave propagating through the edge region 32c are the same as each other. Since the load film 40a and the load film 40d have the same thickness as each other, the acoustic velocity of the acoustic wave propagating through the edge region 32a and the acoustic velocity of the acoustic wave propagating through the edge region 32d are the same as each other. The acoustic velocity of the propagating acoustic wave in the central region 31b is the same as that in the central region 31a. The phrase “the acoustic velocities in the edge regions are the same” means that a difference between a ratio of an acoustic velocity difference between one edge region and the central region to the acoustic velocity in the central region and a ratio of an acoustic velocity difference between the other edge region and the central region to the acoustic velocity in the central region is 0.3% or less, may be 0.2% or less, and may be 0.1% or less (the same applies hereinafter). The fact that the acoustic velocities in the central regions are the same allows a case where the ratio of the difference in acoustic velocity between the central regions to the acoustic velocity in one of the central regions is 0.1% or less (the same applies hereinafter).

Since the number of the electrode finger 22b in the gap regions 33c and 33d is smaller than that in the central region 31b, the acoustic velocity of the acoustic wave propagating through the gap regions 33c and 33d is higher than the acoustic velocity of the acoustic wave propagating through the central region 31b. The acoustic velocity of the acoustic wave propagating through the first busbar region 34 is higher than the acoustic velocity of the acoustic wave propagating through the gap regions 33c and 33d, for example. The acoustic velocity of the acoustic wave propagating through the second busbar region 35 is higher than the acoustic velocity of the acoustic wave propagating through the first busbar region 34, for example. The edge regions 32c and 32d are low acoustic velocity regions in which the acoustic velocity of the acoustic wave is lower than that in the central region 31b, and the gap regions 33c and 33d are high acoustic velocity regions in which the acoustic velocity of the acoustic wave is higher than that in the central region 31b, and thus, the piston mode can be realized.

The acoustic velocity of the acoustic wave is the acoustic velocity of a surface acoustic wave (for example, an SH wave) that propagates on the surface of the piezoelectric layer 10. The acoustic velocity of the acoustic wave can be calculated by, for example, V=(E/(2 ·ρ·(1+ν)))^{1/2}. V is an acoustic velocity of the acoustic wave, E is a Young's modulus, ρ is a density, and ν is a Poisson's ratio.

In order to realize the piston mode, it is preferable that the length of the central region in the Y direction and the length of the edge region in the Y direction satisfy a certain relationship. For example, in the first IDT 20a, the length of the central region 31a in the Y direction is preferably larger than the total length of the edge regions 32a and 32b in the Y direction. The length of each of the edge regions 32a and 32b in the Y direction is preferably 0.05 λ or more and 2 λ or less, and more preferably 0.1 λ or more and 1 λ or less. The length of each of the gap regions 33a and 33b in the Y direction is preferably 0.1 λ or more and 2 λ or less, and more preferably 0.2 λ or more and 1 λ or less. The same applies to the second IDT 20b.

### Simulation 2

A simulation for measuring a real part Real (Y) and an absolute value |Y| of admittance was performed on the first embodiment and the second comparative example. In the second comparative example, the simulation was performed on models A and B in which the thickness of the load film 90 was varied. In the first embodiment, the simulation was performed on a model C. The simulation conditions are as follows.

Simulation Conditions Common to Models A, B, and C
Wavelength λ of acoustic wave: 2.2 μm
Piezoelectric layers 10 and 60:42° rotated Y-cut X-propagation lithium tantalate layer
Metal films 26 and 76: aluminum film having thickness of 220 nm
Metal films 42 and 92: gold film having thickness of 1 μm
Anisotropy coefficient of piezoelectric layers 10 and 60:0.3
Duty ratio of electrodes fingers 22a, 22b, and 72:50 %
Length of central regions 31a, 31b, and 81 in Y direction: 15 λ
Length of edge regions 32a to 32d and 82 in Y direction: 0.6 λ
Length of gap region 33a to 33d and 83 in Y direction: 100 nm
Length of first busbar region 34 (common busbars 24c and 74c) in Y direction: 1 μm
Length of second busbar region 35 in Y direction: 20 μm
Ratio (V_{C}−V_{A})/V_{A} of difference between acoustic velocity V_{C} in gap region and acoustic velocity V_{A} in central region to acoustic velocity V_{A} in central region: +3.0 %
Ratio (V_{D}−V_{A})/V_{A} of difference between acoustic velocity V_{D} in first busbar region and acoustic velocity V_{A} in central region to acoustic velocity V_{A} in central region: +4.0 %
Ratio (V_{E}−V_{A})/V_{A} of difference between acoustic velocity V_{E} in second busbar region and acoustic velocity V_{A} in central region to acoustic velocity V_{A} in central region: +10 %

### Conditions of Model A

Load film 90: niobium oxide film having thickness of 16 nm
Ratio (V_{B}−V_{A})/V_{A} of difference between acoustic velocity V_{B} in edge region 82 and acoustic velocity V_{A} in central region 81 to acoustic velocity V_{A} in central region 81: −1.5 %

Conditions of Model B
Load film 90: niobium oxide film having thickness of 21 nm
Ratio (V_{B}−V_{A})/V_{A} of difference between acoustic velocity V_{B} in edge region 82 and acoustic velocity V_{A} in central region 81 to acoustic velocity V_{A} in central region 81: −2.0 %

Conditions of Model C
Load films 40a and 40d: niobium oxide film having thickness of 21 nm
Load films 40b and 40c: niobium oxide film having thickness of 16 nm
Ratio (V_{B}−V_{A})/V_{A} of difference between acoustic velocity V_{B} in edge regions 32a and 32d and acoustic velocity V_{A} in central regions 31a and 31b to acoustic velocity V_{A} in central regions 31a and 31b: −2.0 %
Ratio (V_{B}−V_{A})/V_{A} of difference between acoustic velocity V_{B} in edge regions 32b and 32c and acoustic velocity V_{A} in central regions 31a and 31b to acoustic velocity V_{A} in central regions 31a and 31b: −1.5 %

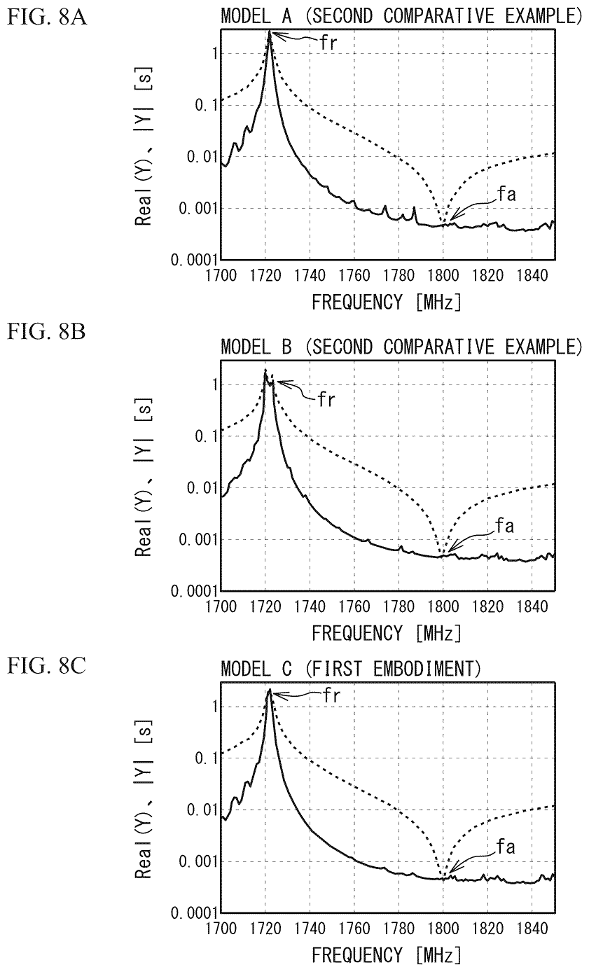

FIGS. 8A to 8C are diagrams illustrating simulation results of real part Real (Y) of admittance and absolute value |Y| of admittance with respect to frequency in simulation 2. FIG. 8A illustrates the results of the model A (the second comparative example), FIG. 8B illustrates the results of the model B (the second comparative example), and FIG. 8C illustrates the results of the model C (the first embodiment). As illustrated in FIG. 8A, in the model A, the transverse mode spurious emissions are generated between the resonant frequency fr and the anti-resonant frequency fa. As illustrated in FIG. 8B, in the model B, the transverse mode spurious emissions between the resonant frequency fr and the anti-resonant frequency fa are reduced as compared with the model A, but a new spurious emission is generated in the vicinity of the resonant frequency fr. On the other hand, as illustrated in FIG. 8C, in the model C, the transverse mode spurious emissions between the resonant frequency fr and the anti-resonant frequency fa are suppressed, and the generation of the new spurious emission in the vicinity of the resonant frequency fr is also suppressed.

From the results of the simulation 2, in the case where one IDT is divided into two IDTs in series, the thicknesses of the load film 40a and the load film 40b are made different from each other in the first IDT 20a, and the thicknesses of the load film 40c and the load film 40d are made different from each other in the second IDT 20b. That is, as illustrated in FIG. 7, in the first IDT 20a, the acoustic velocity profile of the acoustic wave from the boundary between the busbar 24a and the electrode fingers 22a to the boundary between the common busbar 24c and the electrode fingers 22a is asymmetric with respect to a center line 46a of the central region 31a. Similarly, in the second IDT 20b, the acoustic velocity profile of the acoustic wave from the boundary between the busbar 24b and the electrode fingers 22b to the boundary between the common busbar 24c and the electrode fingers 22b is asymmetric with respect to a center line 46b of the central region 31b. Thus, even when one IDT is divided into two IDTs in series, spurious emissions such as transverse mode spurious emissions can be suppressed.

### Modifications

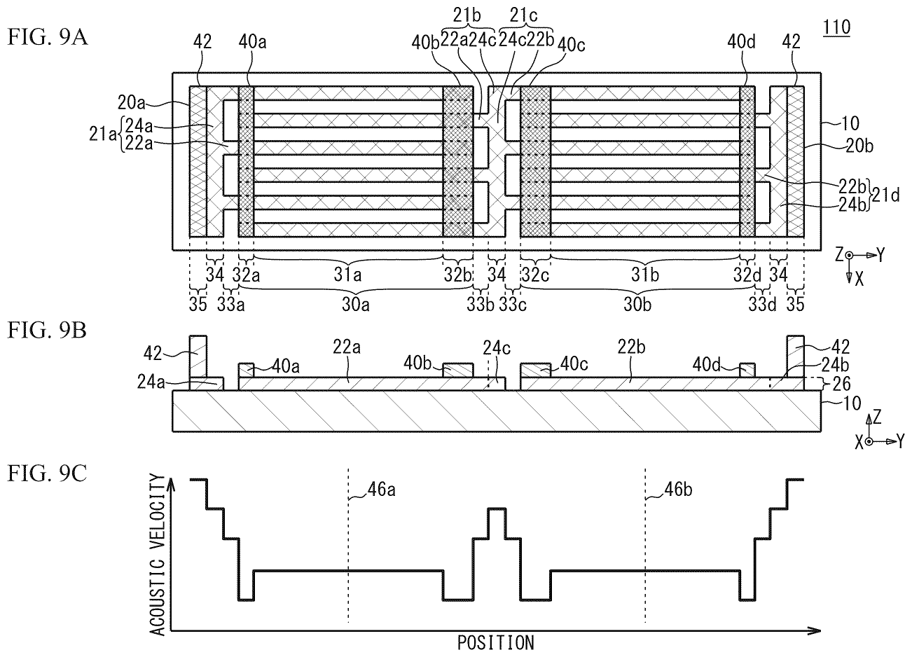

FIG. 9A is a plan view of an acoustic wave device 110 according to a modification of the first embodiment, FIG. 9B is a cross-sectional view of the acoustic wave device 110, and FIG. 9C is a diagram illustrating the acoustic velocity of an acoustic wave. In the first modification of the first embodiment, the reflector 25 is not illustrated for the sake of clarity of the drawing (the same applies to the second to sixth embodiments below). As illustrated in FIG. 9A and FIG. 9B, in the modification of the first embodiment, the load film 40a and the load film 40b have the same thickness but different lengths in the Y direction in the first IDT 20a. Similarly, in the second IDT 20b, the load film 40c and the load film 40d have the same thickness, but have different lengths in the Y direction. The lengths of the load films in the Y direction being different means that, for example, the difference in the lengths of the load films in the Y direction is 0.1 λ or more, may be 0.15 λ or more, and may be 0.2 λ or more. The load film 40 b may be longer or shorter than the load film 40a in the Y direction. The load film 40c may be longer or shorter than the load film 40d in the Y direction. The load film 40a and the load film 40d have the same length in the Y direction and the same thickness, and the load film 40b and the load film 40c have the same length in the Y direction and the same thickness.

As illustrated in FIG. 9C, since in the first IDT 20a, the load film 40a and the load film 40b have the same thickness, the acoustic velocities of the acoustic waves in the edge region 32a and the edge region 32b are the same as each other. On the other hand, since the lengths of the load film 40a and the load film 40b in the Y direction are different from each other, the lengths of the edge region 32a and the edge region 32b in the Y direction in which the acoustic velocity of the acoustic wave is lower than that in the central region 31a are different from each other. Therefore, the acoustic velocity profile of the acoustic wave from the boundary between the busbar 24a and the electrode fingers 22a to the boundary between the common busbar 24c and the electrode fingers 22a is asymmetric with respect to the center line 46a of the central region 31a. For the same reason, also in the second IDT 20b, the acoustic velocity profile of the acoustic wave from the boundary between the busbar 24b and the electrode fingers 22b to the boundary between the common busbar 24c and the electrode fingers 22b is asymmetric with respect to the center line 46b of the central region 31b. The other configurations of the modification of the first embodiment are the same as those of the first embodiment, and thus the description thereof will be omitted.

The first embodiment and the modification of the first embodiment may be combined to make both the thickness and the length in the Y direction different between the load film 40a and the load film 40b. Similarly, both the thickness and the length in the Y direction may be different between the load film 40c and the load film 40d.

According to the first embodiment and the modification thereof, the first IDT 20a and the second IDT 20b are connected in series by sharing one common busbar 24c. The first IDT 20a and the second IDT 20b are located at both ends in the Y direction. In the first IDT 20a, the load film 40a provided in the edge region 32a and the load film 40b provided in the edge region 32b are different from each other in at least one of the thickness and the length in the Y direction. Also in the second IDT 20b, the load film 40c provided in the edge region 32c and the load film 40d provided in the edge region 32d are different from each other in at least one of the thickness and the length in the Y direction. That is, in the first IDT 20a, the acoustic velocity profile of the acoustic wave from the boundary between the electrode fingers 22a of the interdigitated electrode 21a and the busbar 24a to the boundary between the electrode fingers 22a of the interdigitated electrode 21b and the common busbar 24c is asymmetric with respect to the center line 46a of the central region 31a. Also in the second IDT 20b, the acoustic velocity of the acoustic wave from the boundary between the electrode fingers 22b of the interdigitated electrode 21c and the common busbar 24c to the boundary between the electrode fingers 22b of the interdigitated electrode 21d and the busbar 24b is asymmetric with respect to the center line 46b of the central region 31b. Accordingly, even when one IDT is divided into the first IDT 20a and the second IDT 20b in series, the piston mode can be established in each of the first IDT 20a and the second IDT 20b, and the transverse mode spurious emissions can be suppressed.

In the first embodiment and the modification thereof, the load film 40b provided in the edge region 32b located near the second IDT 20b of the first IDT 20a and the load film 40c provided in the edge region 32c located near the first IDT 20a of the second IDT 20b have the same thickness and the same length in the Y direction. The load film 40a provided in the edge region 32a of the first IDT 20a located on the opposite side of the second IDT 20b and the load film 40d provided in the edge region 32d of the second IDT 20b located on the opposite side of the first IDT 20a have the same thickness and length in the Y direction. This makes it possible to establish the piston mode in each of the first IDT 20a and the second IDT 20b, and suppress the transverse mode spurious emissions.

### SECOND EMBODIMENT

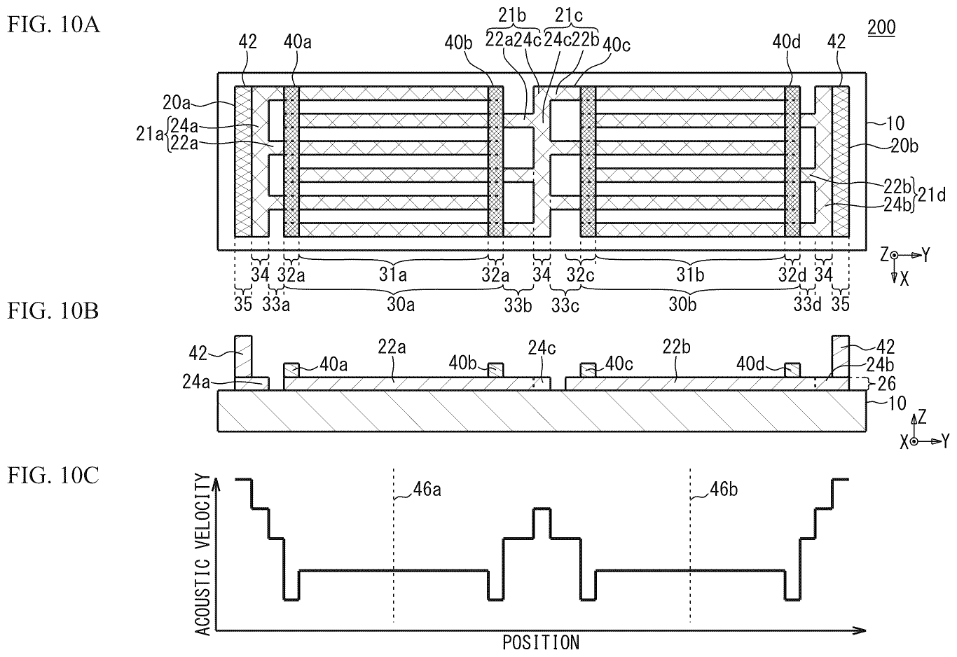

FIG. 10A is a plan view of an acoustic wave device 200 according to a second embodiment, FIG. 10B is a cross-sectional view of the acoustic wave device 200, and FIG. 10C is a diagram illustrating the acoustic velocity of an acoustic wave. As illustrated in FIG. 10A and FIG. 10B, in the second embodiment, the load film 40a and the load film 40b have the same thickness and the same length in the Y direction in the first IDT 20a. In the second IDT 20b, the load film 40c and the load film 40d have the same thickness and the same length in the Y direction. Alternatively, in the first IDT 20a, the length of the gap region 33a and the length of the gap region 33b in the Y direction are different from each other. Similarly, in the second IDT 20b, the length of the gap region 33c and the length of the gap region 33d in the Y direction are different from each other. The lengths of the gap regions in the Y direction being different means that, for example, the difference in the lengths in the Y direction is 0.1 λ or more, may be 0.15 λ or more, and may be 0.2 λ or more. The gap region 33b may be longer or shorter than the gap region 33a in the Y direction. The gap region 33c may be longer or shorter than the gap region 33d in the Y direction. The gap region 33a and the gap region 33d have the same length in the Y direction, and the gap region 33b and the gap region 33c have the same length in the Y direction. The lengths of the gap regions in the Y direction being the same allows a case where the difference in the length in the Y direction is less than 0.01 λ, and may be 0.005 λ or less.

As illustrated in FIG. 10C, in the first IDT 20a, the lengths in the Y direction of the gap region 33a and the gap region 33b in which the acoustic velocity of the acoustic wave is higher than that in the central region 31a are different from each other. Therefore, the acoustic velocity profile of the acoustic wave from the boundary between the busbar 24a and the electrode fingers 22a to the boundary between the common busbar 24c and the electrode fingers 22a is asymmetric with respect to the center line 46a of the central region 31a. For the same reason, also in the second IDT 20b, the acoustic velocity profile of the acoustic wave from the boundary between the busbar 24b and the electrode fingers 22b to the boundary between the common busbar 24c and the electrode fingers 22b is asymmetric with respect to the center line 46b of the central region 31b. The other configurations of the second embodiment are the same as those of the first embodiment, and thus the description thereof will be omitted.

According to the second embodiment, in the first IDT 20a, the distance between the electrode fingers 22a of the interdigitated electrode 21a and the common busbar 24c of the interdigitated electrode 21b (i.e., the length of the gap region 33b in the Y direction) is different from the distance between the busbar 24a of the interdigitated electrode 21a and the electrode fingers 22a of the interdigitated electrode 21b (i.e., the length of the gap region 33a in the Y direction). Also in the second IDT 20b, the distance between the electrode fingers 22b of the interdigitated electrode 21d and the common busbar 24c of the interdigitated electrode 21c (i.e., the length of the gap region 33c in the Y direction) is different from the distance between the busbar 24b of the interdigitated electrode 21d and the electrode fingers 22b of the interdigitated electrode 21c (i.e., the length of the gap region 33d in the Y direction). Therefore, in the first IDT 20a, the acoustic velocity profile of the acoustic wave from the boundary between the electrode fingers 22a of the interdigitated electrode 21a and the busbar 24a to the boundary between the electrode fingers 22a of the interdigitated electrode 21b and the common busbar 24c is asymmetric with respect to the center line 46a of the central region 31a. Also in the second IDT 20b, the acoustic velocity profile of the acoustic wave from the boundary between the electrode fingers 22b of the interdigitated electrode 21c and the common busbar 24c to the boundary between the electrode fingers 22b of the interdigitated electrode 21d and the busbar 24b is asymmetric with respect to the center line 46b of the central region 31b. Accordingly, even when one IDT is divided into the first IDT 20a and the second IDT 20b in series, the piston mode can be established in each of the first IDT 20a and the second IDT 20b, and the transverse mode spurious emissions can be suppressed.

The distance between the common busbar 24c of the interdigitated electrode 21b and the electrode fingers 22a of the interdigitated electrode 21a (i.e., the length of the gap region 33b in the Y direction) is the same as the distance between the common busbar 24c of the interdigitated electrode 21c and the electrode fingers 22a of the interdigitated electrode 21d (i.e., the length of the gap region 33c in the Y direction). The distance between the busbar 24a of the interdigitated electrode 21a and the electrode fingers 22a of the interdigitated electrode 21b (i.e., the length of the gap region 33a in the Y direction) is the same as the distance between the busbar 24b of the interdigitated electrode 21d and the electrode fingers 22b of the interdigitated electrode 21c (i.e., the length of the gap region 33d in the Y direction). This makes it possible to establish the piston mode in each of the first IDT 20a and the second IDT 20b, and suppress the transverse mode spurious emissions.

### THIRD EMBODIMENT

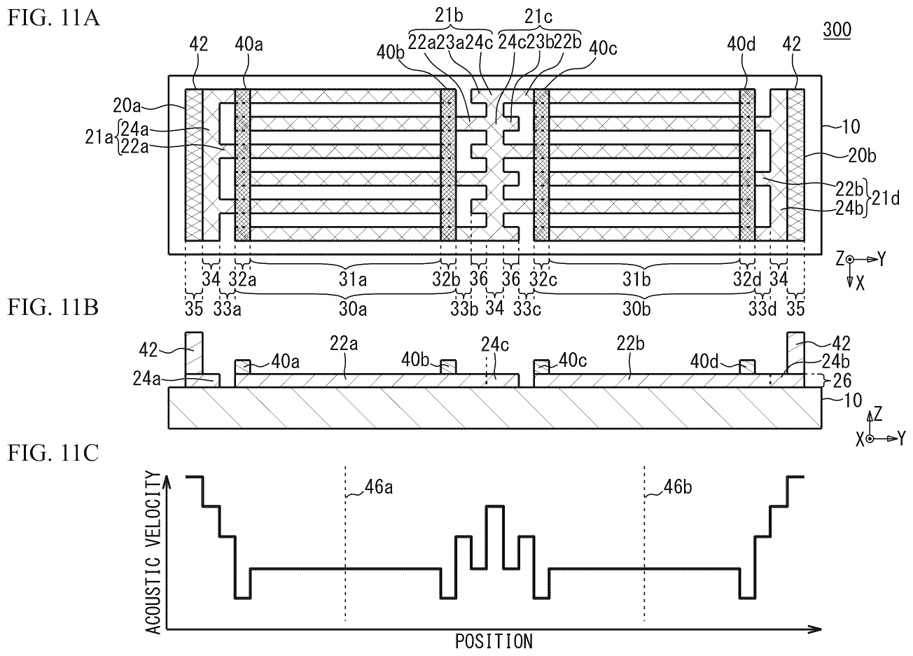

FIG. 11A is a plan view of an acoustic wave device 300 according to a third embodiment, FIG. 11B is a cross-sectional view of the acoustic wave device 300, and FIG. 11C is a diagram illustrating the acoustic velocity of an acoustic wave. As illustrated in FIGS. 11A and 11B, in the third embodiment, the load film 40a and the load film 40b have the same thickness and the same length in the Y direction in the first IDT 20a, similarly to the second embodiment. Also in the second IDT 20b, the load film 40c and the load film 40d have the same thickness and the same length in the Y direction. Alternatively, in the first IDT 20a, the interdigitated electrode 21b has a plurality of dummy electrode fingers 23a connected to the common busbar 24c, but the interdigitated electrode 21a does not have dummy electrode fingers. Also in the second IDT 20b, the interdigitated electrode 21c includes a plurality of dummy electrode fingers 23b connected to the common busbar 24c, but the interdigitated electrode 21d does not include a dummy electrode finger. Regions where the dummy electrode fingers 23a and 23b are provided are referred to as dummy regions 36. In the case where the interdigitated electrodes 21a and 21d do not include dummy electrode fingers, for example, the lengths of the dummy electrode fingers 23a and 23b in the Y direction are, for example, 0.1 λ or more, may be 0.15 λ or more, and may be 0.2 λ or more.

As illustrated in FIG. 11C, the acoustic velocity of the acoustic wave propagating through the dummy region 36 is the same as the acoustic velocity of the acoustic wave propagating through the central regions 31a and 31b. In the first IDT 20a, since the interdigitated electrode 21b includes the dummy electrode fingers 23a, and the interdigitated electrode 21a does not include a dummy electrode finger, the acoustic velocity profile of the acoustic wave from the boundary between the busbar 24a and the electrode fingers 22a to the boundary between the common busbar 24c and the electrode fingers 22a is asymmetric with respect to the center line 46a of the central region 31a. For the same reason, also in the second IDT 20b, the acoustic velocity profile of the acoustic wave from the boundary between the busbar 24b and the electrode fingers 22b to the boundary between the common busbar 24c and the electrode fingers 22b is asymmetric with respect to the center line 46b of the central region 31b. The other configurations of the third embodiment are the same as those of the first embodiment, and thus the description thereof will be omitted.

### Modifications

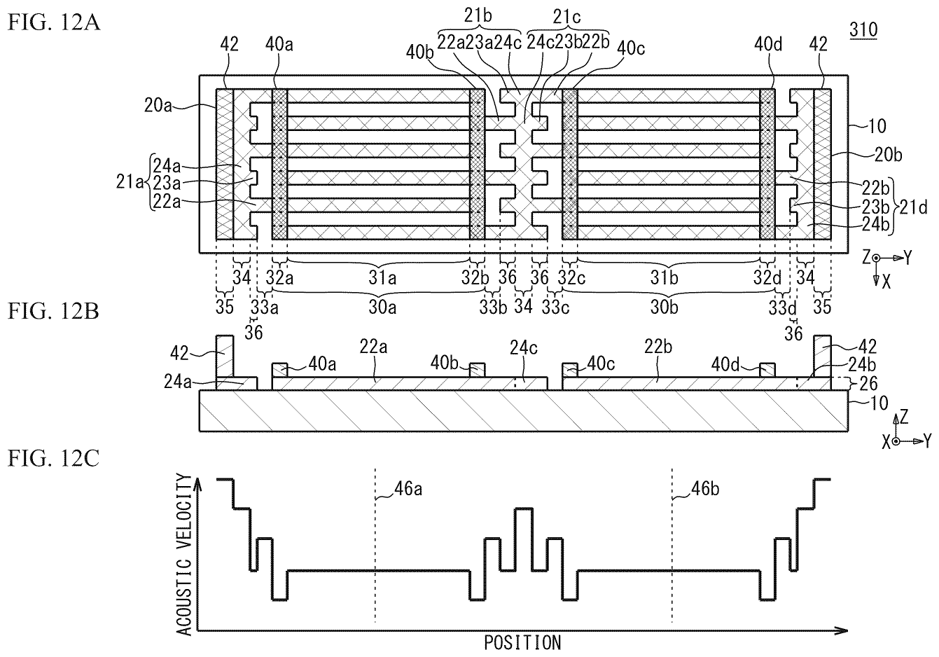

FIG. 12A is a plan view of an acoustic wave device 310 according to a modification of the third embodiment, FIG. 12B is a cross-sectional view of the acoustic wave device 310, and FIG. 12C is a diagram illustrating the acoustic velocity of an acoustic wave. As illustrated in FIGS. 12A and 12B, in the modification of the third embodiment, in the first IDT 20a, in addition to the interdigitated electrode 21b including the plurality of dummy electrode fingers 23a, and the interdigitated electrode 21a also includes the plurality of dummy electrode fingers 23a. The dummy electrode fingers 23a of the interdigitated electrode 21a and the dummy electrode fingers 23a of the interdigitated electrode 21b have different lengths in the Y direction. Similarly, in the second IDT 20b, in addition to the interdigitated electrode 21c including the plurality of dummy electrode fingers 23b, the interdigitated electrode 21d also includes the plurality of dummy electrode fingers 23b. The dummy electrode fingers 23b of the interdigitated electrode 21c and the dummy electrode fingers 23b of the interdigitated electrode 21d have different lengths in the Y direction. The lengths of the dummy electrode fingers in the Y direction being different means that, for example, the difference in the lengths of the dummy electrode fingers in the Y direction is 0.1 λ or more, may be 0.15 λ or more, and may be 0.2 λ or more. The length of the dummy electrode fingers 23a of the interdigitated electrode 21a in the Y direction is the same as the length of the dummy electrode fingers 23b of the interdigitated electrode 21d in the Y direction. The length of the dummy electrode fingers 23a of the interdigitated electrode 21b in the Y direction is the same as the length of the dummy electrode fingers 23b of the interdigitated electrode 21c in the Y direction. The lengths of the dummy electrode fingers in the Y direction being the same allows a case where the difference in the length in the Y direction is less than 0.1 λ, and may be less than 0.05 λ.

As illustrated in FIG. 12C, in the first IDT 20a, since the dummy electrode fingers 23a of the interdigitated electrode 21a and the dummy electrode fingers 23a of the interdigitated electrode 21b have different lengths in the Y direction, the acoustic velocity profile of the acoustic wave from the boundary between the busbar 24a and the electrode fingers 22a to the boundary between the common busbar 24c and the electrode fingers 22a is asymmetric with respect to the center line 46a of the central region 31a. For the same reason, in the second IDT 20b, the acoustic velocity profile of the acoustic wave from the boundary between the busbar 24b and the electrode fingers 22b to the boundary between the common busbar 24c and the electrode fingers 22b is asymmetric with respect to the center line 46b of the central region 31b. The other configurations of the modification of the third embodiment are the same as those of the third embodiment, and thus the description thereof will be omitted.

In the third embodiment and the modification thereof, in the first IDT 20a, the distance between the electrode fingers 22a of the interdigitated electrode 21a and the common busbar 24c of the interdigitated electrode 21b is different from the distance between the busbar 24a of the interdigitated electrode 21a and the electrode fingers 22a of the interdigitated electrode 21b. In the second IDT 20b, the distance between the electrode fingers 22b of the interdigitated electrode 21c and the busbar 24b of the interdigitated electrode 21d is different from the distance between the common busbar 24c of the interdigitated electrode 21c and the electrode fingers 22b of the interdigitated electrode 21d. Therefore, in the first IDT 20a, the acoustic velocity of the acoustic wave from the boundary between the electrode fingers 22a of the interdigitated electrode 21a and the busbar 24a to the boundary between the electrode fingers 22a of the interdigitated electrode 21b and the common busbar 24c is asymmetric with respect to the center line 46a of the central region 31a. In the second IDT 20b, the acoustic velocity of the acoustic wave from the boundary between the electrode fingers 22b of the interdigitated electrode 21c and the common busbar 24c to the boundary between the electrode fingers 22b of the interdigitated electrode 21c and the busbar 24b is asymmetric with respect to the center line 46b of the central region 31b. Accordingly, even when one IDT is divided into the first IDT 20a and the second IDT 20b in series, the piston mode can be established in each of the first IDT 20a and the second IDT 20b, and the transverse mode spurious emissions can be suppressed.

In the third embodiment and the modification thereof, at least one of the interdigitated electrodes 21a and 21b of the first IDT 20a includes the dummy electrode fingers 23a. The length of the dummy electrode fingers 23a in the Y direction is different between the interdigitated electrode 21a and the interdigitated electrode 21b. At least one of the interdigitated electrodes 21c and 21d of the second IDT 20b includes the dummy electrode fingers 23b. The length of the dummy electrode fingers 23b in the Y direction is different between the interdigitated electrode 21c and the interdigitated electrode 21d. This makes it possible to establish the piston mode in each of the first IDT 20a and the second IDT 20b, and suppress the transverse mode spurious emissions.

### FOURTH EMBODIMENT

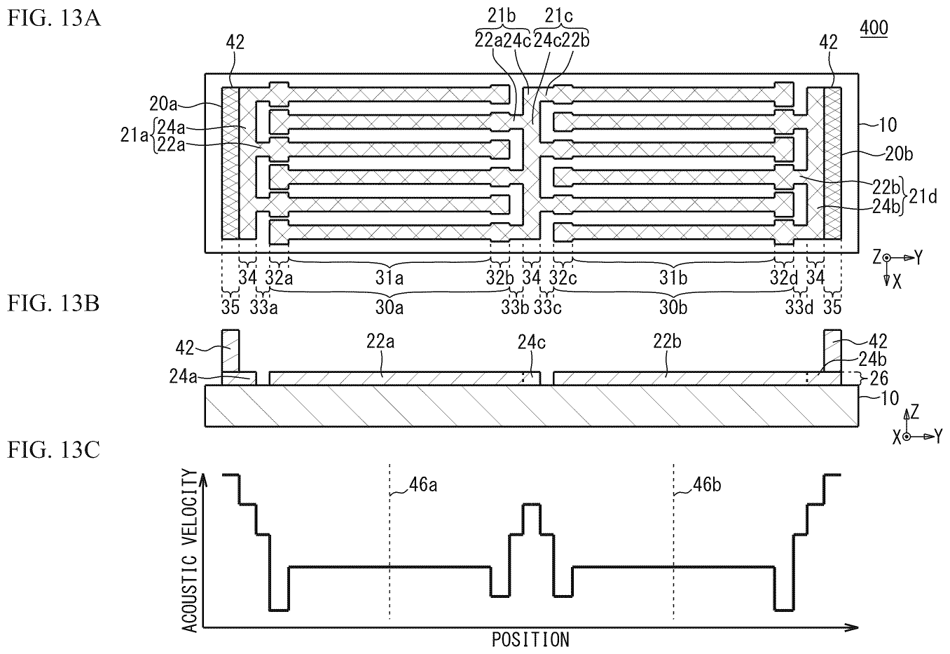

FIG. 13A is a plan view of an acoustic wave device 400 according to a fourth embodiment, FIG. 13B is a cross-sectional view of the acoustic wave device 400, and FIG. 13C is a diagram illustrating the acoustic velocity of an acoustic wave. As illustrated in FIGS. 13A and 13B, in the fourth embodiment, the load film is not provided in the edge regions 32a to 32d. Alternatively, in the first IDT 20a, the lengths of the electrode fingers 22a in the X direction in the edge regions 32a and 32b are larger than the length of the electrode fingers 22a in the X direction in the central region 31a. The lengths of the electrode fingers 22a in the X direction in the edge region 32a are larger than the lengths of the electrode fingers 22a in the X direction in the edge region 32b. Similarly, in the second IDT 20b, the lengths of the electrode fingers 22b in the X direction in the edge regions 32c and 32d are larger than the lengths of the electrode fingers 22b in the X direction in the central region 31b. The lengths of the electrode fingers 22b in the X direction in the edge region 32d are larger than the length of the electrode fingers 22b in the X direction in the edge region 32c. The lengths of the electrode fingers 22a in the X direction and the Y direction in the edge region 32a are the same as the lengths of the electrode fingers 22b in the X direction and the Y direction in the edge region 32d. The lengths of the electrode finger 22a in the X direction and the Y direction in the edge region 32b are the same as the lengths of the electrode finger 22a in the X direction and the Y direction in the edge region 32c. The lengths of the electrode fingers in the X direction being the same allows a case where the difference in length is less than 0.05 λ. The lengths of the electrode fingers in the Y direction being the same allows a case where the difference in length is less than 0.1 λ.

As illustrated in FIG. 13C, since in the first IDT 20a, the lengths of the electrode fingers 22a in the edge region 32a and 32b in the X direction are larger than the lengths of the electrode fingers 22a in the central region 31a in the X direction, the acoustic velocity of the acoustic wave in the edge region 32a and 32b is lower than the acoustic velocity of the acoustic wave in the central region 31a. Since the lengths of the electrode finger 22a in the edge region 32a in the X direction is larger than the lengths of the electrode finger 22a in the edge region 32b in the X direction, the acoustic velocity of the acoustic wave in the edge region 32a is lower than the acoustic velocity of the acoustic wave in the edge region 32b. Therefore, the acoustic velocity profile of the acoustic wave from the boundary between the busbar 24a and the electrode-finger 22a to the boundary between the common-busbar 24c and the electrode-finger 22a is asymmetric with respect to the center line 46a of the central region 31a. For the same reason, in the second IDT20b, the acoustic velocity profile of the acoustic wave from the boundary between the busbar 24b and the electrode fingers 22b to the boundary between the common busbar 24c and the electrode fingers 22b is asymmetric with respect to the center line 46b of the central region 31b. The other configurations of the fourth embodiment are the same as those of the first embodiment, and thus the description thereof will be omitted.

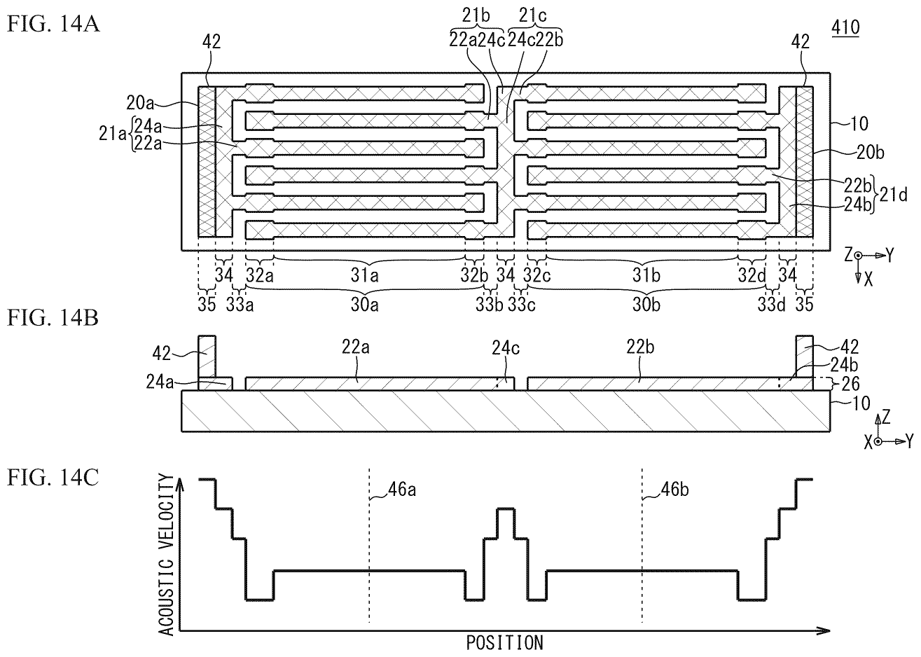

FIG. 14A is a plan view of an acoustic wave device 410 according to a modification of the fourth embodiment, FIG. 14B is a cross-sectional view of the acoustic wave device 400, and FIG. 14C is a diagram illustrating the acoustic velocity of an acoustic wave. As illustrated in FIGS. 14A and 14B, in the modification of the fourth embodiment, in the first IDT 20a, the lengths of the electrode fingers 22a in the X direction are the same as each other in the edge region 32a and the edge region 32b, but the lengths of the electrode fingers 22a in the Y direction are different from each other in the edge region 32a and the edge region 32b. Similarly, also in the second IDT 20b, the lengths of the electrode fingers 22b in the X direction are the same as each other in the edge region 32c and the edge region 32d, but the lengths of the electrode fingers 22b in the Y direction are different from each other in the edge region 32c and the edge region 32d. The lengths of the electrode fingers in the Y direction being different means that the difference in the length in the Y direction is, for example, 0.1 λ or more, may be 0.15 λ or more, and may be 0.2 λ or more. The edge region 32a may be longer or shorter than the edge region 32b in the Y direction. The edge region 32d may be longer or shorter than the edge region 32c in the Y direction.

As illustrated in FIG. 14C, since in the first IDT 20a, the lengths of the electrode fingers 22a in the X direction are the same as each other in the edge region 32a and the edge region 32b, the acoustic velocities of the acoustic waves in the edge region 32a and the edge region 32b are the same as each other. Since the lengths of the edge region 32a and the edge region 32b in the Y direction are different from each other, the lengths of the edge region 32a and the edge region 32b in the Y direction in which the acoustic velocity of the acoustic wave is lower than that in the central region 31a are different from each other. Therefore, the acoustic velocity profile of the acoustic wave from the boundary between the busbar 24a and the electrode fingers 22a to the boundary between the common busbar 24c and the electrode fingers 22a is asymmetric with respect to the center line 46a of the central region 31a. For the same reason, in the second IDT 20b, the acoustic velocity profile of the acoustic wave from the boundary between the busbar 24b and the electrode fingers 22b to the boundary between the common busbar 24c and the electrode fingers 22b is asymmetric with respect to the center line 46b of the central region 31b. The other configurations of the modification of the fourth embodiment are the same as those of the fourth embodiment, and thus the description thereof will be omitted.

The fourth embodiment and the modification of the fourth embodiment may be combined to make both the length in the X direction and the length in the Y direction different between the edge region 32a and the edge region 32b. Similarly, both the length in the X direction and the length in the Y direction may be different between the edge region 32c and the edge region 32d.

According to the fourth embodiment and the modification thereof, in the first IDT 20a, at least one of the lengths of the electrode fingers 22a in the X direction and the lengths of the electrode fingers 22a in the Y direction is different between the edge region 32a and the edge region 32b. In the second IDT 20b, at least one of the lengths of the electrode fingers 22b in the X direction and the lengths of the electrode fingers 22b in the Y direction is different between the edge region 32c and the edge region 32d. Therefore, in the first IDT 20a, the acoustic velocity of the acoustic wave from the boundary between the electrode fingers 22a of the interdigitated electrode 21a and the busbar 24a to the boundary between the electrode fingers 22a of the interdigitated electrode 21b and the common busbar 24c is asymmetric with respect to the center line 46a of the central region 31a. In the second IDT 20b, the acoustic velocity of the acoustic wave from the boundary between the electrode fingers 22b of the interdigitated electrode 21c and the common busbar 24c to the boundary between the electrode fingers 22b of the interdigitated electrode 21d and the busbar 24b is asymmetric with respect to the center line 46b of the central region 31b. Accordingly, even when one IDT is divided into the first IDT 20a and the second IDT 20b in series, the piston mode can be established in each of the first IDT 20a and the second IDT 20b, and the transverse mode spurious emissions can be suppressed.

In the fourth embodiment and the modification thereof, the length in the X direction and the length in the Y direction of the electrode fingers 22a of the first IDT 20a in the edge region 32b located near the second IDT 20b are the same as the length in the X direction and the length in the Y direction of the electrode fingers 22b of the second IDT 20b in the edge region 32c located near the first IDT 20a. The length in the X direction and the length in the Y direction of the electrode fingers 22a of the first IDT 20a in the edge region 32a located on the opposite side of the second IDT 20b are the same as the length in the X direction and the length in the Y direction of the electrode fingers 22b of the second IDT 20b in the edge region 32d located on the opposite side of the first IDT 20a. This makes it possible to establish the piston mode in each of the first IDT 20a and the second IDT 20b, and suppress the transverse mode spurious emissions.

### FIFTH EMBODIMENT

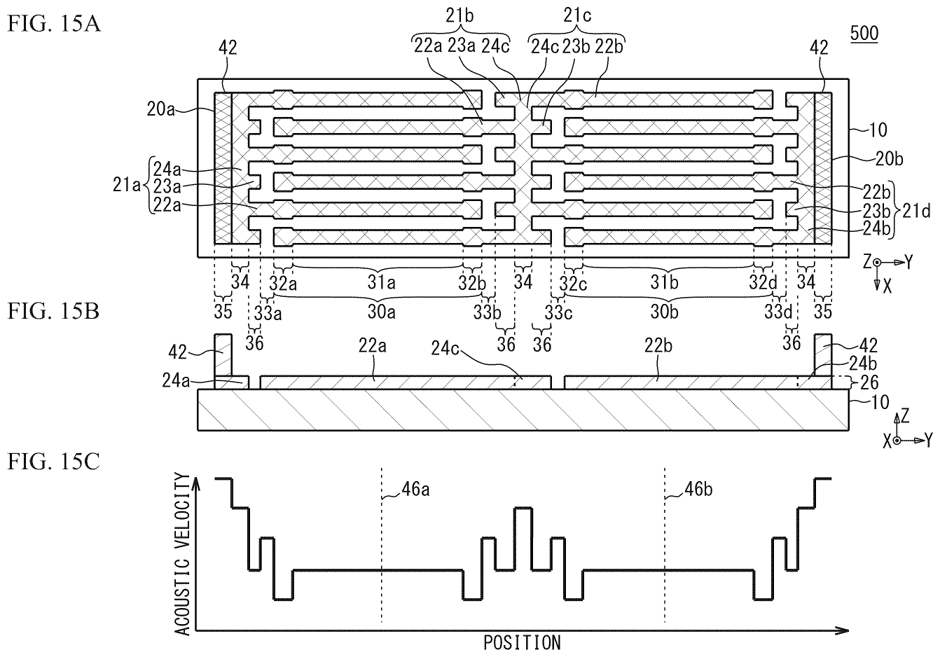

FIG. 15A is a plan view of an acoustic wave device 500 according to a fifth embodiment, FIG. 15B is a cross-sectional view of the acoustic wave device 500, and FIG. 15C is a diagram illustrating the acoustic velocity of an acoustic wave. As illustrated in FIGS. 15A and 15B, in the fifth embodiment, the load film is not provided in the edge regions 32a to 32d, similarly to the fourth embodiment. Alternatively, in the first IDT 20a, the lengths of the electrode fingers 22a in the X direction in the edge regions 32a and 32b are larger than the lengths of the electrode fingers 22a in the X direction in the central region 31a. Similarly, in the second IDT 20b, the lengths of the electrode fingers 22b in the X direction in the edge regions 32c and 32d are larger than the lengths of the electrode fingers 22b in the X direction in the central region 31b. In the edge regions 32a to 32d, the electrode fingers 22a and the electrode fingers 22b have the same length in the X direction and the same length in the Y direction.

In the first IDT 20a, the distance in the Y direction between the electrode fingers 22a of the interdigitated electrode 21a and the common busbar 24c of the interdigitated electrode 21b is different from the distance in the Y direction between the busbar 24a of the interdigitated electrode 21a and the electrode fingers 22a of the interdigitated electrode 21b. In the second IDT 20b, the distance in the Y direction between the electrode fingers 22b of the interdigitated electrode 21d and the common busbar 24c of the interdigitated electrode 21c is different from the distance in the Y direction between the busbar 24b of the interdigitated electrode 21d and the electrode fingers 22b of the interdigitated electrode 21c. The expression “the distances in the Y direction are different” means that, for example, the difference in the distance is 0.1 λ or more, may be 0.15 λ or more, and may be 0.2 λ or more. The distance in the Y direction between the electrode fingers 22a of the interdigitated electrode 21a and the common busbar 24c of the interdigitated electrode 21b is the same as the distance in the Y direction between the electrode fingers 22b of the interdigitated electrode 21d and the common busbar 24c of the interdigitated electrode 21c. The distance in the Y direction between the busbar 24a of the interdigitated electrode 21a and the electrode fingers 22a of the interdigitated electrode 21b is the same as the distance in the Y direction between the busbar 24a of the interdigitated electrode 21d and the electrode fingers 22b of the interdigitated electrode 21c. The expression “the distances are the same” means that the difference in distance is 0.01 λ or less, and may be 0.005 λ or less.

In the first IDT 20a, each of the interdigitated electrodes 21a and 21b includes the plurality of dummy electrode fingers 23a, as in the modification of the third embodiment. The dummy electrode fingers 23a of the interdigitated electrode 21a and the dummy electrode fingers 23a of the interdigitated electrode 21b have different lengths in the Y direction. In the second IDT 20b, each of the interdigitated electrodes 21c and 21d includes the plurality of dummy electrode fingers 23b. The dummy electrode fingers 23b of the interdigitated electrode 21c and the dummy electrode fingers 23b of the interdigitated electrode 21d have different lengths in the Y direction.

As illustrated in FIG. 15C, in the first IDT 20a, since the dummy electrode fingers 23a of the interdigitated electrode 21a and the dummy electrode fingers 23a of the interdigitated electrode 21b have different lengths in the Y direction, the acoustic velocity profile of the acoustic wave from the boundary between the busbar 24a and the electrode fingers 22a to the boundary between the common busbar 24c and the electrode fingers 22a is asymmetric with respect to the center line 46a of the central region 31a. For the same reason, in the second IDT 20b, the acoustic velocity profile of the acoustic wave from the boundary between the busbar 24b and the electrode fingers 22b to the boundary between the common busbar 24c and the electrode fingers 22b is asymmetric with respect to the center line 46b of the central region 31b. The other configurations of the fifth embodiment are the same as those of the first embodiment, and thus the description thereof will be omitted.

According to the fifth embodiment, in the first IDT 20a, the distance between the electrode fingers 22a of the interdigitated electrode 21a and the common busbar 24c of the interdigitated electrode 21b is different from the distance between the busbar 24a of the interdigitated electrode 21a and the electrode fingers 22a of the interdigitated electrode 21b. In the second IDT 20b, the distance between the electrode fingers 22b of the interdigitated electrode 21c and the busbar 24b of the interdigitated electrode 21d is different from the distance between the common busbar 24c of the interdigitated electrode 21c and the electrode fingers 22b of the interdigitated electrode 21d. Therefore, in the first IDT 20a, the acoustic velocity of the acoustic wave from the boundary between the electrode fingers 22a of the interdigitated electrode 21a and the busbar 24a to the boundary between the electrode finger 22a of the interdigitated electrode 21b and the common busbar 24c is asymmetric with respect to the center line 46a of the central region 31a. In the second IDT 20b, the acoustic velocity of the acoustic wave from the boundary between the electrode finger 22b of the interdigitated electrode 21c and the common busbar 24c to the boundary between the electrode finger 22b of the interdigitated electrode 21d and the busbar 24b is asymmetric with respect to the center line 46b of the central region 31b. Accordingly, even when one IDT is divided into the first IDT 20a and the second IDT 20b in series, the piston mode can be established in each of the first IDT 20a and the second IDT 20b, and the transverse mode spurious emissions can be suppressed.

In the fifth embodiment, the distance between the common busbar 24c of the interdigitated electrode 21b and the electrode fingers 22a of the interdigitated electrode 21a are the same as the distances between the common busbar 24c of the interdigitated electrode 21c and the electrode fingers 22a of the interdigitated electrode 21d. The distance between the busbar 24a of the interdigitated electrode 21a and the electrode fingers 22a of the interdigitated electrode 21b are the same as the distance between the busbar 24b of the interdigitated electrode 21d and the electrode fingers 22b of the interdigitated electrode 21c. This makes it possible to establish the piston mode in each of the first IDT 20a and the second IDT 20b, and suppress the transverse mode spurious emissions.

In the fifth embodiment, the lengths of the dummy electrode fingers 23a in the Y direction are different between the interdigitated electrode 21a and the interdigitated electrode 21b of the first IDT 20a. The lengths of the dummy electrode finger 23b in the Y direction are different between the interdigitated electrode 21d and the interdigitated electrode 21c of the second IDT 20b. This makes it possible to establish the piston mode in each of the first IDT 20a and the second IDT 20b, and suppress the transverse mode spurious emissions.

In the fifth embodiment, one of the interdigitated electrodes 21a and 21b in the first IDT 20a may not include the dummy electrode fingers 23a as in the third embodiment. In the second IDT 20b, one of the interdigitated electrodes 21c and 21d may not include the dummy electrode fingers 23b. In the case where no dummy electrode finger is provided, the lengths of the dummy electrode fingers in the Y direction are 0, and thus the lengths of the dummy electrode fingers in the Y direction are different from each other.

### SIXTH EMBODIMENT

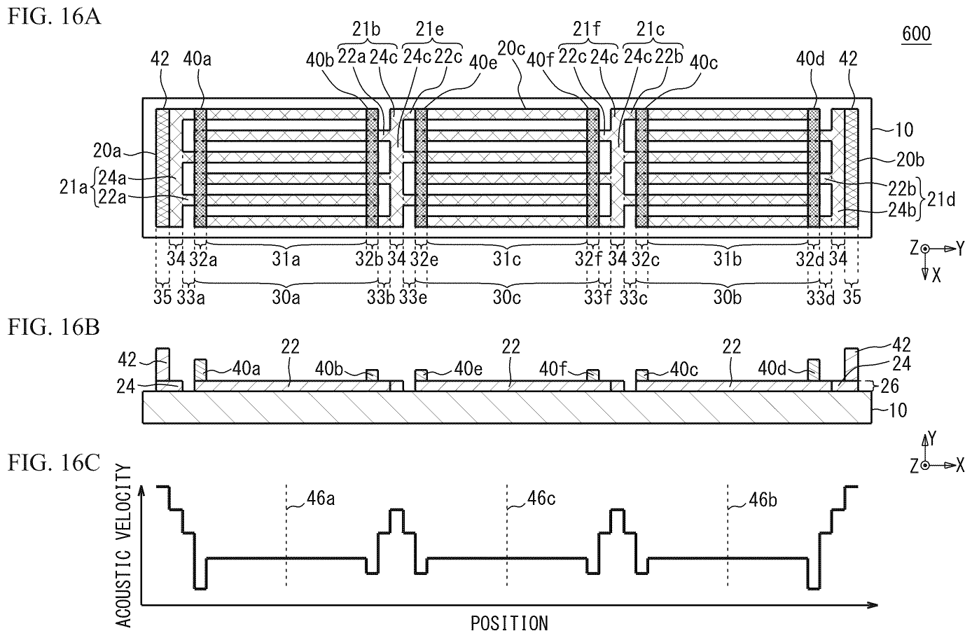

A sixth embodiment is an example in which one IDT is divided into three IDTs in series. FIG. 16A is a plan view of an acoustic wave device 600 according to a sixth embodiment, FIG. 16B is a cross-sectional view of the acoustic wave device 600, and FIG. 16C is a diagram illustrating the acoustic velocity of an acoustic wave. As illustrated in FIGS. 16A and 16B, in the sixth embodiment, a third IDT 20c is connected between the first IDT 20a and the second IDT 20b. The third IDT 20c includes a pair of interdigitated electrodes 21e and 21f each including a plurality of electrode fingers 22c and the common busbar 24c to which the plurality of electrode fingers 22c are connected. The interdigitated electrode 21e shares the common busbar 24c with the interdigitated electrode 21b. The interdigitated electrode 21f shares the common busbar 24c with the interdigitated electrode 21c. In the third IDT 20c, load films 40e and 40f provided in edge regions 32e and 32f located at the edges of an intersection region 30c in the Y direction have the same thickness and the same length in the Y direction.

As illustrated in FIG. 16C, since in the third IDT 20c, the thicknesses and the lengths in the Y direction of the load film 40e and the load film 40f are the same as each other, the acoustic velocities of the acoustic waves in the edge region 32e and the edge region 32f are the same as each other. Therefore, in the third IDT 20c, the acoustic velocity profile of the acoustic wave from one boundary between the common busbar 24c and the electrode fingers 22c to the other boundary is symmetrical with respect to a center line 46c of a central region 31 c. The other configurations of the sixth embodiment are the same as those of the first embodiment, and thus the description thereof will be omitted.

As in the sixth embodiment, one IDT may be divided into three or more IDTs in series, such as the first IDT 20a, the second IDT 20b, and the third IDT 20c. In this case, the IDTs located at both ends in the Y direction among the plurality of IDTs are the first IDT 20a and the second IDT 20b described in the first embodiment to the fifth embodiment. The first IDT 20a and the second IDT 20b are point-symmetrical or line-symmetrical with respect to the center point or the center line of all the IDTs divided in series.

In addition, in the first embodiment to the sixth embodiments, the length of the common busbar 24 c in the Y direction is 0.3 λ or more and 2.0 λ or less. Accordingly, it is possible to suppress an increase in electric resistance of the common busbar 24c, and to propagate the acoustic wave while suppressing a loss even when the acoustic wave leaks between the first IDT 20a and the second IDT 20b. From the viewpoint of suppressing an increase in the electric resistance of the common busbar 24c, the length of the common busbar 24c in the Y direction is preferably 0.4 λ or more, more preferably 0.5 λ or more, and still more preferably 0.6 λ or more. From the viewpoint of suppressing the loss even when the acoustic wave propagates between the first IDT 20a and the second IDT 20b, the length of the common busbar 24c in the Y direction is preferably 1.8 λ or less, more preferably 1.6 λ or less, and still more preferably 1.4 λ or less.

### SEVENTH EMBODIMENT

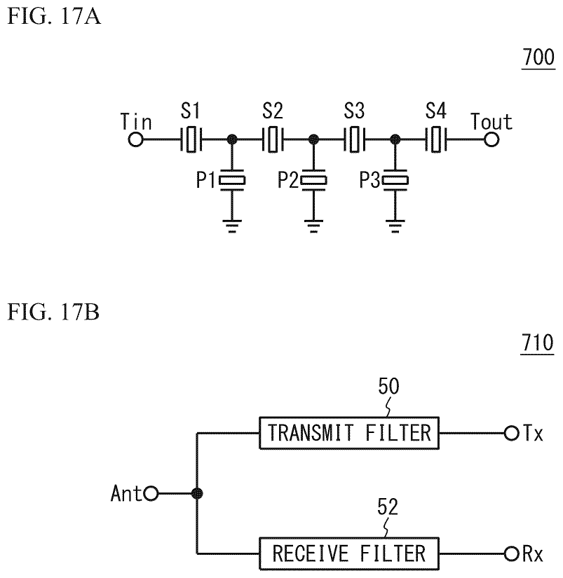

FIG. 17A is a circuit diagram of a filter 700 according to a seventh embodiment. As illustrated in FIG. 17A, one or more series resonators S1 to S4 are connected in series between an input terminal Tin and an output terminal Tout. One or more parallel resonators P1 to P3 are connected in parallel between the input terminal Tin and the output terminal Tout. The acoustic wave devices of the first embodiment to the sixth embodiment can be used for at least one of the series resonators S1 to S4 and the parallel resonators P1 to P3. The number of series resonators and parallel resonators, and the like can be set as appropriate. Although the ladder-type filter is illustrated as an example of the filter, the filter may be a multi-mode filter.

FIG. 17B is a circuit diagram of a duplexer 710 in accordance with a modification of the seventh embodiment. As illustrated in FIG. 17B, a transmit filter 50 is connected between a common terminal Ant and a transmit terminal Tx. A receive filter 52 is connected between the common terminal Ant and a receive terminal Rx. The transmit filter 50 passes through signals in the transmit band to the common terminal Ant as transmission signals among the high frequency signals input from the transmit terminal Tx, and suppresses signals with other frequencies. The receive filter 52 passes through signals in the receive band to the receive terminal Rx as receive signals among the high frequency signals input from the common terminal Ant, and suppresses signals with other frequencies. At least one of the transmit filter 50 and the receive filter 52 may be the filter of the sixth embodiment. Although a duplexer is illustrated as an example of a multiplexer, a triplexer or a quadplexer may be used.

Although the embodiments of the present disclosure have been described in detail above, the present disclosure is not limited to the specific embodiments, and various change, substitutions, and alterations could be made hereto without departing from the spirit and scope of the claimed invention.

What is claimed is:

1. An acoustic wave device comprising:
a piezoelectric layer;
a plurality of interdigital transducers (IDTs) provided on the piezoelectric layer so as to be connected in series to each other, each of the IDTs including a pair of interdigitated electrodes, each of the pair of interdigitated electrodes including a plurality of electrode fingers and a busbar to which the plurality of electrode fingers are connected, an intersection region in which the plurality of electrode fingers of the pair of interdigitated electrodes intersect each other including a pair of edge regions located at edges of the plurality of electrode fingers in a longitudinal direction and a central region located between the pair of edge regions; and
a load film provided in the pair of edge regions and not provided in the central region in each of the plurality of IDTs;
wherein the plurality of IDTs are connected in series by sharing a common busbar as the busbar between adjacent IDTs among the plurality of IDTs, and
wherein in each of a first IDT and a second IDT located at both ends in the longitudinal direction among the plurality of IDTs, the load film provided in one of the pair of edge regions and the load film provided in another of the pair of edge regions are different in at least one of a thickness and a length in the longitudinal direction.

2. The acoustic wave device according to claim 1,
wherein the load film provided in the edge region located near the second IDT of the pair of edge regions of the first IDT and the load film provided in the edge region located near the first IDT of the pair of edge regions of the second IDT have the same thickness and the same length in the longitudinal direction, and
wherein the load film provided in the edge region located on an opposite side of the second IDT of the pair of edge regions of the first IDT and the load film provided in the edge region located on an opposite side of the first IDT of the pair of edge regions of the second IDT have the same thickness and the same length in the longitudinal direction.

3. The acoustic wave device according to claim 1,
wherein in each of the first IDT and the second IDT located at both ends in the longitudinal direction among the plurality of IDTs, a distance between the plurality of electrode fingers of one of the pair of interdigitated electrodes and the busbar of another of the pair of interdigitated electrodes is different from a distance between the busbar of the one of the pair of interdigitated electrodes and the plurality of electrode fingers of the another of the pair of interdigitated electrodes.

4. An acoustic wave device comprising:
a piezoelectric layer; and
a plurality of interdigital transducers (IDTs) provided on the piezoelectric layer so as to be connected in series to each other, each of the IDTs including a pair of interdigitated electrodes, each of the pair of interdigitated electrodes including a plurality of electrode fingers and a busbar to which the plurality of electrode fingers are connected, an intersection region in which the plurality of electrode fingers of the pair of interdigitated electrodes intersect each other including a pair of edge regions located at edges of the plurality of electrode fingers in a longitudinal direction and a central region located between the pair of edge regions, lengths of the plurality of electrode fingers in a transverse direction of the plurality of electrode fingers in the pair of edge regions being larger than lengths of the plurality of electrode fingers in the transverse direction in the central region;
wherein the plurality of IDTs are connected in series by sharing a common busbar as the busbar between adjacent IDTs among the plurality of IDTs, and
wherein in each of a first IDT and a second IDT located at both ends in the longitudinal direction among the plurality of IDTs, at least one of lengths in the longitudinal direction and lengths in the transverse direction of the plurality of electrode fingers is different between one and another of the pair of edge regions.

5. The acoustic wave device according to claim 4,
wherein the lengths of the plurality of electrode fingers in the longitudinal direction and the transverse direction in an edge region located near the second IDT of the pair of edge regions of the first IDT are the same as the lengths of the plurality of electrode fingers in the longitudinal direction and the transverse direction in an edge region located near the first IDT of the pair of edge regions of the second IDT, and
wherein the lengths of the plurality of electrode fingers in the longitudinal direction and the transverse direction in an edge region located on an opposite side of the second IDT of the pair of edge regions of the first IDT are the same as the lengths of the plurality of electrode fingers in the longitudinal direction and the transverse direction in an edge region located on an opposite side of the first IDT of the pair of edge regions of the second IDT.

6. The acoustic wave device according to claim 4,
wherein in each of the first IDT and the second IDT located at both ends in the longitudinal direction among the plurality of IDTs, a distance between the plurality of electrode fingers of one of the pair of interdigitated electrodes and the busbar of another of the pair of interdigitated electrodes is different from a distance between the busbar of the one of the pair of interdigitated electrodes and the plurality of electrode fingers of the another of the pair of interdigitated electrodes.

7. The acoustic wave device according to claim 1,
wherein a distance between the busbar of one first interdigitated electrode located near the second IDT of the pair of interdigitated electrodes of the first IDT and the plurality of electrode fingers of another first interdigitated electrode located on an opposite side of the second IDT is the same as a distance between the busbar of one second interdigitated electrode located near the first IDT of the pair of interdigitated electrodes of the second IDT and the plurality of electrode fingers of another second interdigitated electrode located on an opposite side of the first IDT, and
wherein a distance between the plurality of electrode fingers of the one first interdigitated electrode and the busbar of the another first interdigitated electrode is the same as a distance between the plurality of electrode fingers of the one second interdigitated electrode and the busbar of the another second interdigitated electrode.

8. The acoustic wave device according to claim 1,
wherein each of the first IDT and the second IDT includes a plurality of dummy electrode fingers connected to the busbar of at least one of the pair of interdigitated electrodes,
wherein, in the pair of interdigitated electrodes of the first IDT, one first interdigitated electrode located near the second IDT and another first interdigitated electrode located on an opposite side of the second IDT have different lengths of the plurality of dummy electrode fingers in the longitudinal direction, and
wherein, in the pair of interdigitated electrodes of the second IDT, one second interdigitated electrode located near the first IDT and another second interdigitated electrode located on an opposite side of the first IDT have different lengths of the plurality of dummy electrode fingers in the longitudinal direction.

9. The acoustic wave device according to claim 4,
wherein a distance between the busbar of one first interdigitated electrode located near the second IDT of the pair of interdigitated electrodes of the first IDT and the plurality of electrode fingers of another first interdigitated electrode located on an opposite side of the second IDT is the same as a distance between the busbar of one second interdigitated electrode located near the first IDT of the pair of interdigitated electrodes of the second IDT and the plurality of electrode fingers of another second interdigitated electrode located on an opposite side of the first IDT, and
wherein a distance between the plurality of electrode fingers of the one first interdigitated electrode and the busbar of the another first interdigitated electrode is the same as a distance between the plurality of electrode fingers of the one second interdigitated electrode and the busbar of the another second interdigitated electrode.

10. The acoustic wave device according to claim 4,
wherein each of the first IDT and the second IDT includes a plurality of dummy electrode fingers connected to the busbar of at least one of the pair of interdigitated electrodes,
wherein, in the pair of interdigitated electrodes of the first IDT, one first interdigitated electrode located near the second IDT and another first interdigitated electrode located on an opposite side of the second IDT have different lengths of the plurality of dummy electrode fingers in the longitudinal direction, and
wherein, in the pair of interdigitated electrodes of the second IDT, one second interdigitated electrode located near the first IDT and another second interdigitated electrode located on an opposite side of the first IDT have different lengths of the plurality of dummy electrode fingers in the longitudinal direction.

11. An acoustic wave device comprising:
a piezoelectric layer; and
a plurality of interdigital transducers (IDTs) provided on the piezoelectric layer so as to be connected in series to each other, each of the IDTs including a pair of interdigitated electrodes, each of the pair of interdigitated electrodes including a plurality of electrode fingers and a busbar to which the plurality of electrode fingers are connected, an intersection region in which the plurality of electrode fingers of the pair of interdigitated electrodes intersect each other including a pair of edge regions located at edges of the plurality of electrode fingers in a longitudinal direction and a central region located between the pair of edge regions, an acoustic velocity of an acoustic wave in the pair of edge regions being lower than that of an acoustic wave in the central region;
wherein the plurality of IDTs are connected in series by sharing a common busbar as the busbar between adjacent IDTs among the plurality of IDTs, and
wherein in each of a first IDT and a second IDT located at both ends in the longitudinal direction among the plurality of IDTs, an acoustic velocity profile of an acoustic wave from a boundary between the plurality of electrode fingers of one of the pair of interdigitated electrodes and the busbar to a boundary between the plurality of electrode fingers of another of the pair of interdigitated electrodes and the busbar is asymmetric with respect to a center of the central region.

12. The acoustic wave device according to claim 1,
wherein a length of the common busbar in the longitudinal direction is 0.6 times or more and 4.0 times or less an average pitch of the plurality of electrode fingers.

13. The acoustic wave device according to claim 4,
wherein a length of the common busbar in the longitudinal direction is 0.6 times or more and 4.0 times or less an average pitch of the plurality of electrode fingers.

14. The acoustic wave device according to claim 11,
wherein a length of the common busbar in the longitudinal direction is 0.6 times or more and 4.0 times or less an average pitch of the plurality of electrode fingers.

15. A filter comprising the acoustic wave device according to claim 1.

16. A multiplexer comprising the filter according to claim 15.
